(19) United States
(12) Patent Application Publication
(10) Pub. No.: US 2016/0163925 A1
(43) Pub. Date: Jun. 9, 2016

(54) SEMICONDUCTOR LIGHT-EMITTING DEVICE AND METHOD OF MANUFACTURING THE SAME

(71) Applicant: Samsung Electronics Co., Ltd., Suwon-si (KR)

(72) Inventors: Su Hyun Jo, Hwaseong-si (KR); Ki Seok Kim, Hwaseong-si (KR); Seong Seok Yang, Hwaseong-si (KR); Yong Il Kim, Seoul (KR); Seung Hwan Lee, Suwon-si (KR)

(21) Appl. No.: 14/958,002

(22) Filed: Dec. 3, 2015

(30) Foreign Application Priority Data
Dec. 8, 2014 (KR) 10-2014-0175195

(51) Int. Cl. H01L 33/22; H01L 33/32; H01L 33/58

(52) U.S. Cl. CPC H01L 33/22; H01L 33/58; H01L 33/32

(57) ABSTRACT

A semiconductor light-emitting device includes a light-emitting structure including a first conductivity-type semiconductor layer, an active layer, and a second conductivity-type semiconductor layer, microstructures regularly arranged on the first conductivity-type semiconductor layer around the light-emitting structure, and a gradient refractive layer on at least a portion of the microstructures, the gradient refractive layer having a lower refractive index than the first conductivity-type semiconductor layer.

### CROSS-REFERENCE TO RELATED APPLICATION

This application claims the priority and benefit of Korean Patent Application No. 10-2014-0175195 filed on Dec. 8, 2014, with the Korean Intellectual Property Office, the inventive concepts of which are incorporated herein by reference.

### BACKGROUND

1. Field

Example embodiments of the present inventive concepts relate to a semiconductor light-emitting device and a method of manufacturing a semiconductor light-emitting device.

2. Description of the Related Art

Semiconductor light-emitting devices, e.g., light emitting diodes (LEDs), are devices including materials for emitting light, and emit light by the conversion of energy generated by electron-hole recombination. LEDs may have advantages, e.g., relatively long lifespans, relatively low power consumption, relatively fast response times, and environmental friendliness, as compared to conventional light sources. Accordingly, LEDs are being widely used as lighting apparatuses, display devices, and light sources, and the development thereof is accordingly being accelerated.

Recently, the range of applications of LEDs has been gradually broadened to include light sources in relatively high-current/high-power applications.

### SUMMARY

Example embodiments of the present inventive concepts provide a semiconductor light-emitting device having improved light extraction efficiency and a method of manufacturing the semiconductor light-emitting device.

According to example embodiments of the present inventive concepts, a semiconductor light-emitting device includes a light-emitting structure including a first conductivity-type semiconductor layer, an active layer, and a second conductivity-type semiconductor layer, microstructures regularly arranged on the first conductivity-type semiconductor layer around the light-emitting structure, and a gradient refractive layer on at least a portion of the microstructures, the gradient refractive layer having a lower refractive index than the first conductivity-type semiconductor layer.

In example embodiments of the present inventive concepts, the microstructures may have a hemispherical structure and a diameter of each of the microstructures may be in a range of 2 μm to 3 μm.

In example embodiments of the present inventive concepts, a height of each of the microstructures may be lower than a height of an interface between the first conductivity-type semiconductor layer and the active layer.

In example embodiments of the present inventive concepts, the microstructures may have one of a hexagonal lattice-shaped array and a tetragonal-lattice shaped array, and a pitch between each of the microstructures may be in a range of 2.5 μm to 8 μm.

In example embodiments of the present inventive concepts, the microstructures may be formed of the same material as the first conductivity-type semiconductor layer.

In example embodiments of the present inventive concepts, a refractive index of the gradient refractive layer may have a value between a refractive index of the first conductivity-type semiconductor layer and a refractive index of silicon oxide.

In example embodiments of the present inventive concepts, the gradient refractive layer may include a plurality of material layers having different refractive indices, and a thickness of each material layer may be in a range of 10 nm to 200 nm.

In example embodiments of the present inventive concepts, the microstructures may be formed of a material having a lower refractive index than the first conductivity-type semiconductor layer. The material having the lower refractive index than the first conductivity-type semiconductor layer may be ZnO, and a refractive index of the gradient refractive layer may have a value between a refractive index of the ZnO and a refractive index of silicon oxide.

In example embodiments of the present inventive concepts, the semiconductor light-emitting device may further include a first electrode connected to the first conductivity-type semiconductor layer, and the microstructures may be on the first conductivity-type semiconductor layer except for an area of the first conductivity-type semiconductor layer including the first electrode.

According to example embodiments of the present inventive concepts, a method of manufacturing a semiconductor light-emitting device includes forming a light-emitting structure by sequentially stacking a first conductivity-type semiconductor layer, an active layer, and a second conductivity-type semiconductor layer, forming a mesa structure exposing at least a portion of the first conductivity-type semiconductor layer and microstructures regularly arranged on at least a portion of the exposed portion of the first conductivity-type semiconductor layer by etching the light-emitting structure in a single etching process, and forming a gradient refractive layer on at least a portion of the microstructures, the gradient refractive layer having a lower refractive index than the first conductivity-type semiconductor layer.

In example embodiments of the present inventive concepts, forming the mesa structure and the microstructures may include forming a photoresist pattern including a first pattern defining the mesa structure and a second pattern defining the microstructures having a smaller size than the mesa structure on the light-emitting structure, and anisotropically etching the light-emitting structure using the photoresist pattern as an etching mask.

In example embodiments of the present inventive concepts, the second pattern may be completely removed during the anisotropically etching.

In example embodiments of the present inventive concepts, the method of manufacturing a semiconductor light-emitting device may further include reflowing the photoresist pattern before the anisotropically etching.

According to example embodiments of the present inventive concepts, a semiconductor light-emitting device includes a first semiconductor layer and an encapsulating material on a substrate, the substrate including a first region and a second region, microstructures between the first semiconductor layer and the encapsulating material in the second region, and a gradient refractive layer between the encapsulating material and at least a portion of the microstructures in the second region, the gradient refractive layer having a lower refractive index than the microstructures and a greater refractive index than the encapsulating material.

In example embodiments of the present inventive concepts, the encapsulating material may be made of one of air and SiO₂.

In example embodiments of the present inventive concepts, the semiconductor light-emitting device may further include a light-emitting structure on the first region of the substrate, the light-emitting structure including the first semiconductor layer, an active layer, and a second semiconductor layer.

In example embodiments of the present inventive concepts, a height of each of the microstructures may be lower than a height of an interface between the first semiconductor layer and the active layer.

In example embodiments of the present inventive concepts, the semiconductor light-emitting device may further include a first electrode on the first semiconductor layer in the second region, an ohmic contact layer on the second semiconductor layer in the first region, and a second electrode on the ohmic contact layer in the first region, wherein the microstructures may be on the first semiconductor layer except for an area of the first semiconductor layer including the first electrode.

In example embodiments of the present inventive concepts, the microstructures may be formed of the same material as the first semiconductor layer.

In example embodiments of the present inventive concepts, the microstructures and the first semiconductor layer may be formed of n-type GaN.

In example embodiments of the present inventive concepts, a refractive index of the gradient refractive layer may have a value between a refractive index of the first semiconductor layer and a refractive index of silicon oxide.

In example embodiments of the present inventive concepts, the microstructures may be formed of a material having a lower refractive index than the first semiconductor layer, the material having the lower refractive index than the first semiconductor layer may be ZnO, and a refractive index of the gradient refractive layer may have a value between a refractive index of the ZnO and a refractive index of silicon oxide.

### BRIEF DESCRIPTION OF DRAWINGS

The above and other aspects, features and advantages of the present inventive concepts will be more clearly understood from the following detailed description taken in conjunction with the accompanying drawings, in which:

FIG. 1 is a plan view schematically illustrating a semiconductor light-emitting device fabricated according to example embodiments of the present inventive concepts;

FIGS. 2A-2B are schematic cross-sectional views of semiconductor light-emitting devices fabricated according to example embodiments of the present inventive concepts;

FIGS. 3A and 3B are enlarged views of areas ‘E’ and ‘N’ of FIG. 1;

FIGS. 4A and 4B are diagrams illustrating modified examples of the embodiments of FIGS. 3A and 3B;

FIGS. 5A to 5C are enlarged diagrams of area ‘G’ of FIG. 2A;

FIG. 6 is a flowchart illustrating a method of manufacturing a semiconductor light-emitting device according to example embodiments of the present inventive concepts;

FIGS. 7A to 7F are cross-sectional views illustrating main processes of manufacturing a semiconductor light-emitting device according to example embodiments of the present inventive concepts;

FIG. 8 is a cross-sectional view of a semiconductor light-emitting device fabricated according to example embodiments of the present inventive concepts;

FIGS. 9A to 9C are cross-sectional views illustrating main processes of manufacturing a semiconductor light-emitting device according to example embodiments of the present inventive concepts;

FIG. 10 is a schematic cross-sectional view of a semiconductor light-emitting device fabricated according to example embodiments of the present inventive concepts;

FIGS. 11A and 11B are enlarged diagrams of area ‘G’ of FIG. 2A;

FIG. 12 is a flowchart illustrating a method of manufacturing a semiconductor light-emitting device according to example embodiments of the present inventive concepts;

FIGS. 13A to 13E are cross-sectional views illustrating main processes of manufacturing a semiconductor light-emitting device according to example embodiments of the present inventive concepts;

FIGS. 14A and 14B are diagrams illustrating a refractive index distribution around microstructures according to example embodiments of the present inventive concepts;

FIG. 15 is a graph illustrating light emission efficiency characteristics according to example embodiments of the present inventive concepts;

FIGS. 16 and 17 are cross-sectional views illustrating semiconductor light-emitting device packages as examples in which a semiconductor light-emitting device fabricated according to example embodiments of the present inventive concepts is applied to a package;

FIG. 18 is the CIE 1931 coordinate system, provided to illustrate a wavelength conversion material usable in the package illustrated in FIG. 17;

FIGS. 19 and 20 illustrate light source modules to which a semiconductor light-emitting device fabricated according to example embodiments of the present inventive concepts is applied;

FIGS. 21 and 22 illustrate examples in which a semiconductor light-emitting device fabricated according to example embodiments of the present inventive concepts is applied to a backlight unit;

FIGS. 23 to 25 illustrate examples in which a semiconductor light-emitting device fabricated according to example embodiments of the present inventive concepts is applied to a lighting apparatus; and

FIG. 26 illustrates an example in which a semiconductor light-emitting device according to example embodiments of the present inventive concepts is applied to a headlamp.

### DETAILED DESCRIPTION

Hereinafter, example embodiments of the present inventive concepts will be described in detail with reference to the accompanying drawings.

The inventive concepts may, however, be exemplified in many different forms and should not be construed as being limited to the specific embodiments set forth herein. Rather, these embodiments are provided so that this disclosure will be thorough and complete, and will fully convey the scope of the inventive concepts to those skilled in the art.

In the drawings, the shapes and dimensions of elements may be exaggerated for clarity, and the same reference numerals will be used throughout to designate the same or like elements. Throughout this disclosure, directional terms such as “upper,” “upper (portion),” “upper surface,” “lower,” “lower (portion),” “lower surface,” or “side surface” may be used to describe the relationship of one element or feature to another, as illustrated in the drawings. It will be understood that such descriptions are intended to encompass different orientations in use or operation in addition to orientations depicted in the drawings.

References throughout this disclosure to “example embodiments” are provided to emphasize particular features, structures, or characteristics, and do not necessarily refer to the same embodiment. Furthermore, the particular features, structures, or characteristics may be combined in any suitable manner in one or more embodiments. For example, a context described in a specific example embodiment may be used in other embodiments, even if it is not described in the other embodiments, unless it is described contrary to or in a manner inconsistent with the context in the other embodiments.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the example embodiments in the detailed description will be described with sectional views as ideal example views of the inventive concepts. Accordingly, shapes of the example views may be modified according to manufacturing techniques and/or allowable errors. Therefore, the example embodiments of the inventive concepts are not limited to the specific shape illustrated in the example views, but may include other shapes that may be created according to manufacturing processes. Areas illustrated in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in example embodiments could be termed a second element in other embodiments without departing from the teachings of the inventive concepts. Example embodiments of the present inventive concepts explained and illustrated herein include their complementary counterparts. The same reference numerals or the same reference designators denote the same elements throughout the specification.

Moreover, example embodiments are described herein with reference to cross-sectional illustrations and/or plane illustrations that are idealized example illustrations. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

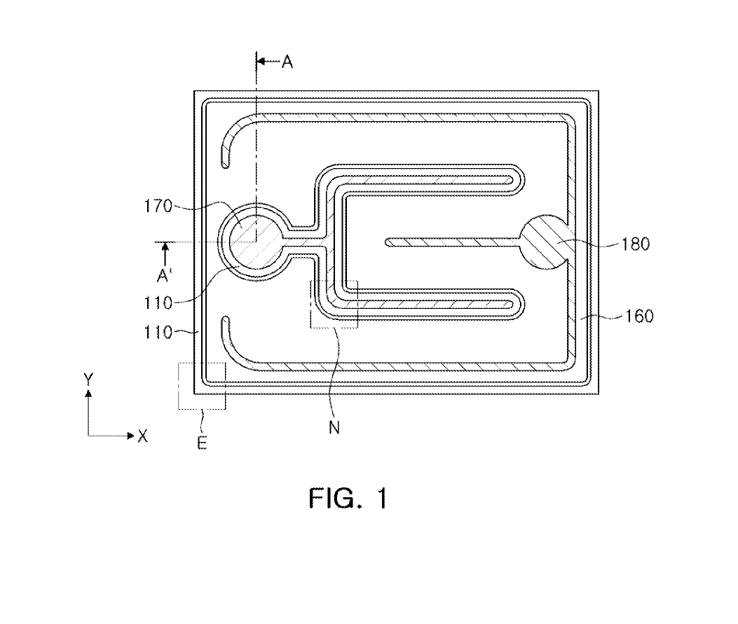

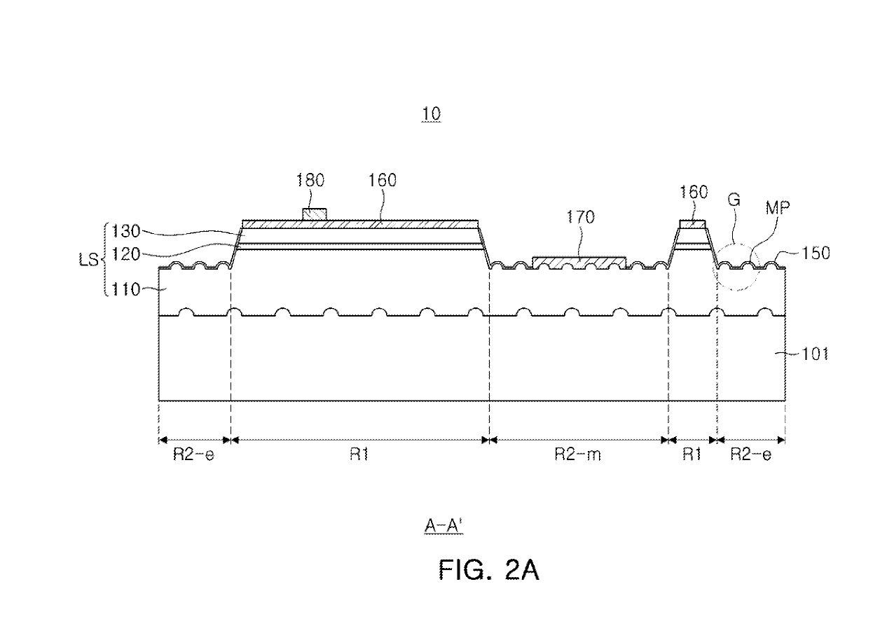

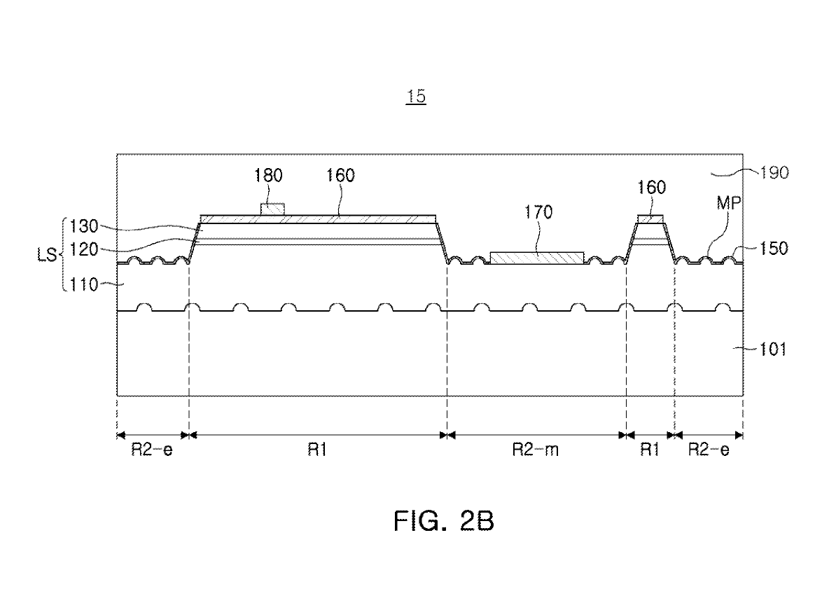

FIG. 1 is a plan view schematically illustrating a semiconductor light-emitting device 10 fabricated according to example embodiments of the present inventive concepts. FIG. 2A is a cross-sectional view taken along line A-A′ of the semiconductor light-emitting device 10 illustrated in FIG. 1. A method of manufacturing the semiconductor light-emitting device 10 will be described later, and structural characteristics of the semiconductor light-emitting device 10 according to example embodiments of the present inventive concepts will be described first.

Referring to FIGS. 1 and 2A, the semiconductor light-emitting device 10 fabricated according to example embodiments of the present inventive concepts may include a light-emitting structure LS disposed on a substrate 101. The light-emitting structure LS may include a first conductivity-type semiconductor layer 110, an active layer 120, and a second conductivity-type semiconductor layer 130. First and second electrodes 170 and 180 for applying driving power may be respectively disposed on the first and second conductivity-type semiconductor layers 110 and 130. The first and second electrodes 170 and 180 may include, but are not limited to, at least one electrode finger connected to a circular pad for more effective current spreading. In addition, an ohmic contact layer 160 may be further disposed between the second conductivity-type semiconductor layer 130 and the second electrode 180 for effective current spreading.

The substrate 101 may be provided as a growth substrate for a semiconductor material, and may use an insulating material, a conductive material, or a semiconductor material, e.g., sapphire, Si, SiC, MgAl₂O₄, MgO, LiAlO₂, LiGaO₂, and GaN. In example embodiments, sapphire having electrically insulating properties may be used. Sapphire is a crystal having Hexa-Rhombo R3c symmetry, has lattice constants of 13.001 Å in a c-axis orientation and 4.758 Å in an a-axis orientation, and has a C-plane (0001), an A-plane (11-20), an R-plane (1-102), and the like. Because the C-plane allows a nitride thin film to be relatively easily grown thereon and is stable even at high temperatures, sapphire is predominantly utilized as a growth substrate for a nitride.

Alternatively, an Si substrate, for example, may be used as the substrate 101. Because the Si substrate is appropriate for providing a relatively large diameter and has relatively low manufacturing costs, mass manufacturing characteristics may be improved. When the Si substrate is used, a buffer layer formed of a material, e.g., AlGaN, may be formed on the substrate 101, and a nitride semiconductor having a given structure may be grown.

Concave-convex portions may be, but is not limited to, formed on an upper surface of the substrate 101, that is, a growth surface for a semiconductor layer. Through the concave-convex portions, crystallinity of the semiconductor layer and light emission efficiency may be improved.

In example embodiments of the present inventive concepts, a buffer layer may be interposed between the substrate 101 and the first conductivity-type semiconductor layer 110. Normally, when a semiconductor layer is grown on a hetero-substrate, the buffer layer may be formed to relieve differences in lattice constants between the hetero-substrate and the semiconductor layer and reduce lattice defects of the semiconductor layer.

For example, when a nitride semiconductor layer is grown as the first conductivity-type semiconductor layer 110 on the substrate 101 formed of sapphire, GaN, AlN, or AlGaN, formed at a relatively lower temperature of 500° C. to 600° C. and not intentionally doped, may be used as a material forming the buffer layer.

The first and second conductivity-type semiconductor layers 110 and 130 may be formed of a nitride semiconductor having a composition of AlₚIn_{q}Ga₁₋p-qN (0≦p<1, 0≦q<1, and 0≦p+q<1), for example. In example embodiments of the present inventive concepts, the first and second conductivity-type semiconductor layers 110 and 130 may be nitride semiconductor layers doped with n-type impurities and p-type impurities, respectively, but are not limited thereto. Conversely, the first and second conductivity-type semiconductor layers 110 and 130 may be nitride semiconductor layers doped with p-type impurities and n-type impurities, respectively.

The active layer 120 may emit light having a predetermined or given wavelength by electron-hole recombination. The active layer 120 may be disposed between the first and second conductivity-type semiconductor layers 110 and 130, and may include a material having a lower energy bandgap than the first and second conductivity-type semiconductor layers 110 and 130. In addition, the active layer 120 may have a multi-quantum well (MQW) structure in which quantum well layers and quantum barrier layers are alternately stacked. For example, when the active layer 120 is a nitride semiconductor, the active layer 120 may have a structure in which quantum well layers formed of In_{y1}Ga_{1-y1}N (0<y₁<1) and quantum barrier layers formed of In_{y2}Ga_{1-y2}N (0≦y₂<y₁) are alternately stacked.

In example embodiments, the active layer 120 may have a single quantum well (SQW) structure including a single quantum well layer.

The ohmic contact layer 160 may allow a current applied to the second electrode 180 to be effectively spread throughout the second conductivity-type semiconductor layer 130. In a device structure in which light generated in the active layer 120 is emitted over the light-emitting structure LS as example embodiments of the present inventive concepts, the ohmic contact layer 160 may include, but is not limited to, a transparent conductive oxide layer having a high level of light transmittance and relatively improved ohmic contact properties. For example, the ohmic contact layer 160 may formed of at one selected from the group consisting of indium tin oxide (ITO), zinc oxide (ZnO), zinc-doped indium tin oxide (ZITO), zinc indium oxide (ZIO), Cu-doped tin oxide (CIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂, and zinc magnesium oxide (Zn₍₁₋ₓ₎MgₓO, 0≦x≦1).

The semiconductor light-emitting device 10 may include the first electrode 170 electrically connected to the first conductivity-type semiconductor layer 110, and the second electrode 180 electrically connected to the second conductivity-type semiconductor layer 130. The first and second electrodes 170 and 180 may be, for example, a material selected from Ag, Al, Ni, Cr, Pd, Cu, Pt, Sn, W, Au, Rh, Ir, Ru, Mg, and Zn. The first and second electrodes 170 and 180 may be formed using a process well-known in the art, e.g., chemical vapor deposition (CVD), sputtering, or electroplating. In addition, the first and second electrodes 170 and 180 may be formed in multiple layers of two or more materials, e.g., Ni/Ag, Zn/Ag, Ni/Al, Zn/Al, Pd/Ag, Pd/Al, Ir/Ag, Ir/Au, Pt/Ag, Pt/Al, or Ni/Ag/Pt. The first and second electrodes 170 and 180 may include at least one electrode finger connected to a circular pad for more effective current spreading.

In example embodiments of the present inventive concepts, the semiconductor light-emitting device 10 may have a mesa structure formed by mesa-etching the second conductivity-type semiconductor layer 130 and the active layer 120 to expose the first conductivity-type semiconductor layer 110. The first conductivity-type semiconductor layer 110 may be partially exposed around the mesa structure. Meanwhile, in FIG. 1, the first conductivity-type semiconductor layer 110 exposed by mesa-etching is illustrated as being disposed in a center portion and on an outermost edge of the semiconductor light-emitting device, but is not limited thereto. An upper surface of the first conductivity-type semiconductor layer 110 exposed in the center portion of the semiconductor light-emitting device may be provided as an area to form the first electrode 170.

In example embodiments of the present inventive concepts, concave-convex patterns may be formed on at least a portion of the first conductivity-type semiconductor layer 110 exposed by mesa-etching. More specifically, microstructures MP regularly arranged on at least a portion of the exposed first conductivity-type semiconductor layer 110 may be formed. The microstructures MP may be formed of the same material as the first conductivity-type semiconductor layer 110, and heights of the microstructures MP may be lower than a height of an interface between the first conductivity-type semiconductor layer 110 and the active layer 120.

The semiconductor light-emitting device 10 of FIG. 2A is encapsulated by air in the atmosphere. Because incident angles of light may be diversified in an interface between the first conductivity-type semiconductor layer 110 and the air surrounding the semiconductor light-emitting device 10 due to the microstructures MP formed on the first conductivity-type semiconductor layer 110, light generated in the active layer 120 may be more easily emitted to an exterior.

Referring to FIG. 2B, a semiconductor light-emitting device 15 includes an encapsulating material 190 on the first and second regions of the substrate 101. The encapsulating material may be made of SiO₂. Because incident angles of light may be diversified in an interface between the first conductivity-type semiconductor layer 110 and the encapsulating material 190 due to the microstructures MP formed on the first conductivity-type semiconductor layer 110, light generated in the active layer 120 may be more easily emitted to an exterior.

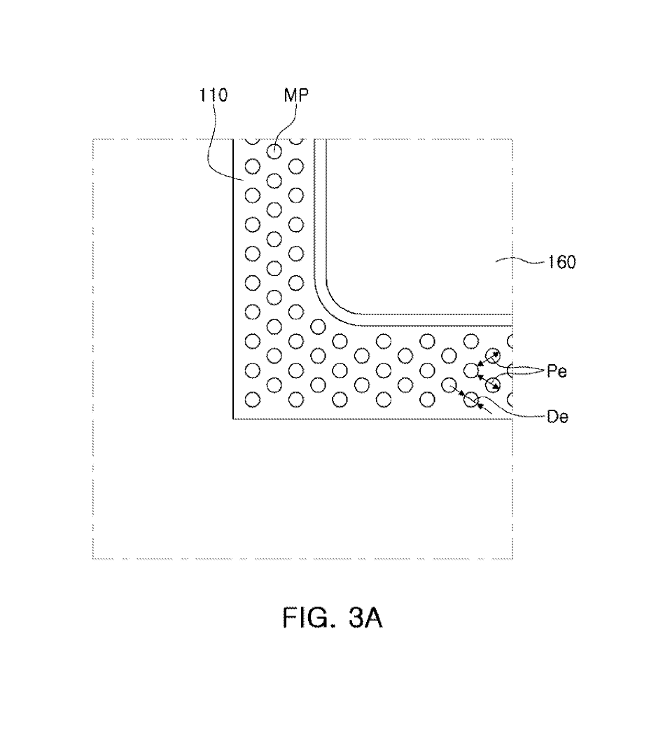

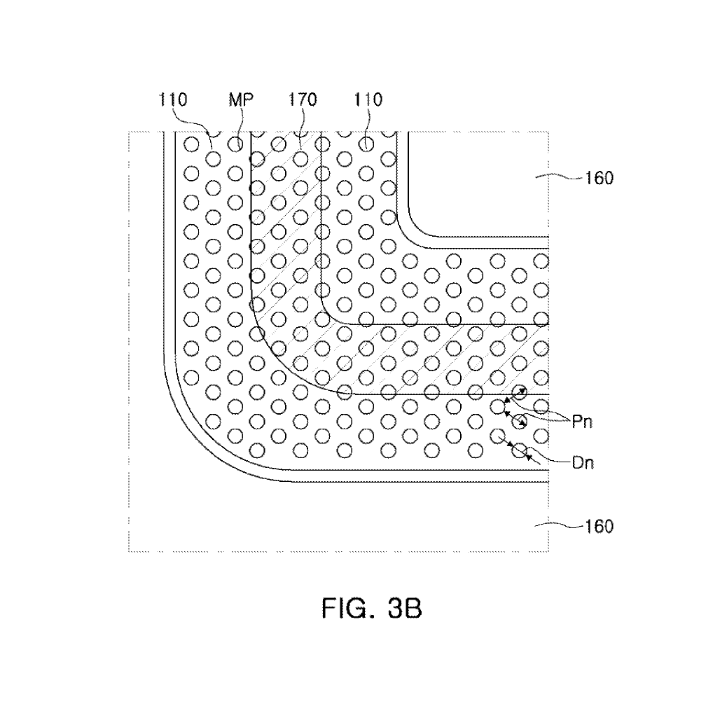

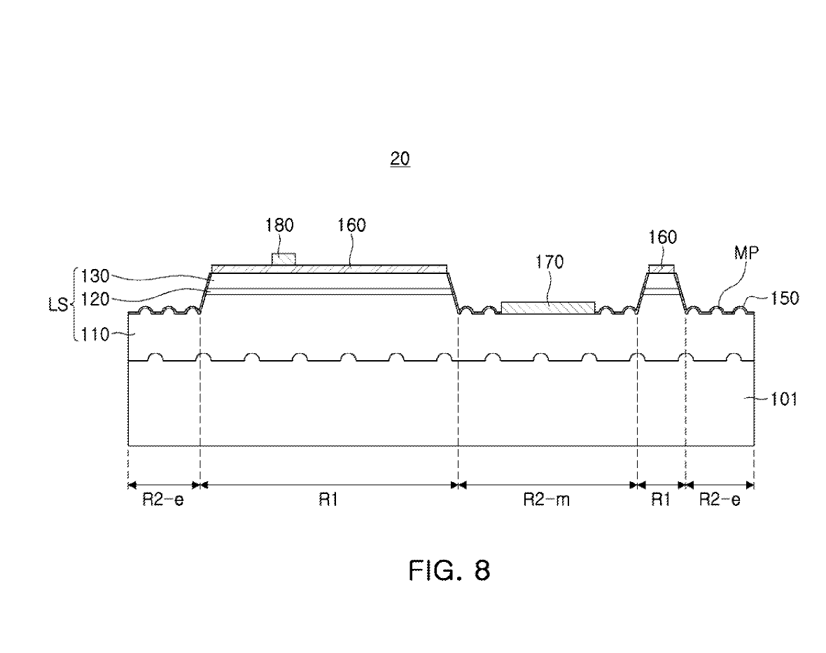

The microstructures MP will be described with reference to FIGS. 3A and 3B, in detail. FIG. 3A is a partially enlarged view of the outermost edge of the semiconductor light-emitting device 10 (area ‘E’ in FIG. 1). FIG. 3B is a partially enlarged view of a center portion of the semiconductor light-emitting device 10 (area ‘N’ in FIG. 1). The microstructures MP formed on the first conductivity-type semiconductor layer 110 exposed by mesa-etching may be arranged in a hexagonal lattice pattern in which virtual lines connecting centers of three adjacent microstructures MP form equilateral triangles, as illustrated in FIGS. 3A and 3B. Each diameter De and Dn of the microstructures MP may be in a range of 2 μm to 3 μm, and each pitch Pe and Pn between the microstructures MP may be in a range of 2.5 μm to 8 μm. Referring to FIG. 3B, the microstructures MP may be formed on the first conductivity-type semiconductor layer 110 below the first electrode 170. In example embodiments, the microstructures MP may not be formed on the first conductivity-type semiconductor layer 110 below the first electrode 170. This will be described in more detail with reference to FIG. 8.

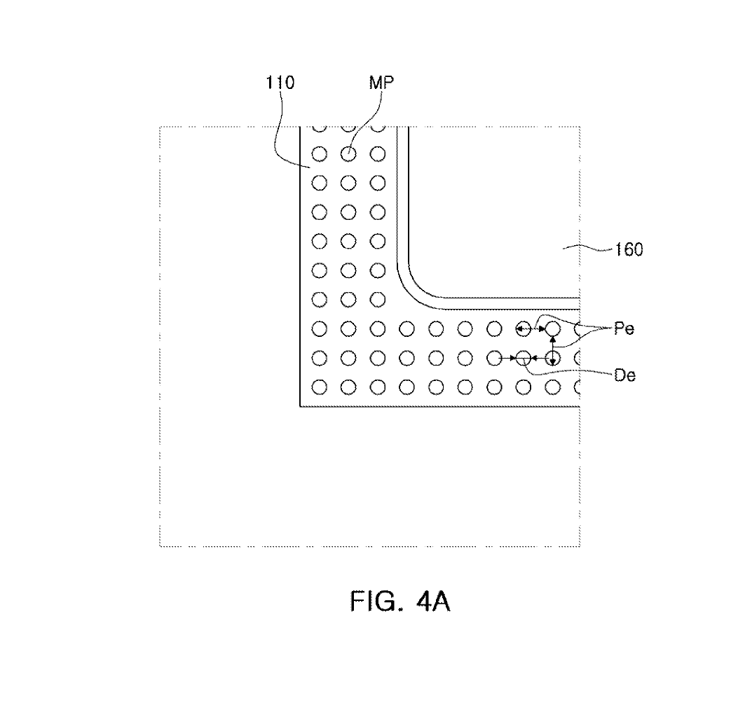

FIGS. 4A and 4B are diagrams illustrating modified examples of the embodiments of FIGS. 3A and 3B. In example embodiments of the inventive concepts, the microstructures MP may be arranged in a tetragonal lattice pattern as illustrated in FIGS. 4A and 4B. Because features other than the arrangement of the microstructures MP may be the same as those described with reference to FIGS. 3A and 3B, duplicated descriptions will be omitted.

Meanwhile, because the microstructures MP are more densely arranged when arranged in the hexagonal lattice pattern as illustrated in FIGS. 3A and 3B than when arranged in the tetragonal lattice pattern as illustrated in FIGS. 4A and 4B, it is more advantageous for the microstructures MP to be arranged in the hexagonal lattice pattern in terms of improving light extraction efficiency.

Meanwhile, in example embodiments, the microstructures MP may be formed on the exposed first conductivity-type semiconductor layer 110 in such a manner that areas with hexagonal lattice pattern arrays and areas with tetragonal lattice pattern arrays are mixed.

In general, a semiconductor light-emitting device may have a problem in that a significant amount of light generated in the active layer 120 is not emitted to an exterior due to total reflection caused by a difference in refractive indices between the light-emitting structure LS and an external material (e.g. air or another encapsulating material). However, according to example embodiments of the present inventive concepts, because incident angles of light may be diversified in an interface between the first conductivity-type semiconductor layer 110 and an external material (e.g. air or another encapsulating material) due to the microstructures MP formed on the first conductivity-type semiconductor layer 110, light generated in the active layer 120 may be more easily emitted to an exterior.

For example, in the case of the semiconductor light-emitting device illustrated in FIG. 1, due to the microstructures MP, light may be easily emitted to an exterior even in the center portion and outermost edge portion in which the first conductivity-type semiconductor layer 110 exposed by mesa-etching is disposed.

Referring again to FIG. 2A, the semiconductor light-emitting device 10 may be divided into a first region R1, including a mesa structure, and a second region R2, including the microstructures MP around the mesa structure. The second region R2 including the microstructures MP may be subdivided into a central portion R2-m and an outermost edge portion R2-e.

The ohmic contact layer 160 may be disposed on the first region R1 including the mesa structure, and the second electrode 180 may be disposed on a portion of the ohmic contact layer 160. The first electrode 170 may be disposed on a portion of the central portion R2-m in the second region R2 including the microstructures MP.

A gradient refractive layer 150 having a lower refractive index than the first conductivity-type semiconductor layer 110 and a greater refractive index than an encapsulating material may be formed on the microstructures MP other than the portion on which the first electrode 170 is disposed. In example embodiments, the gradient refractive layer 150 may be formed on sidewalls of the mesa structure.

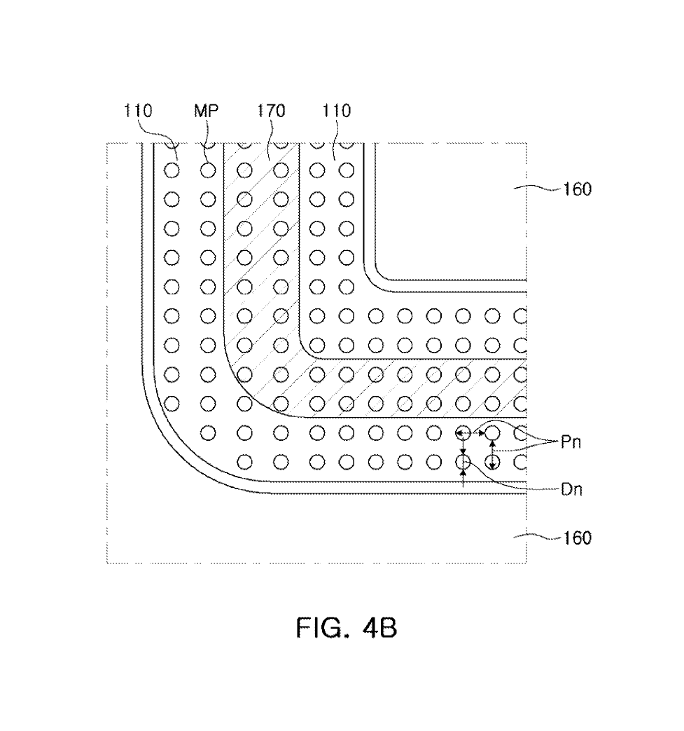

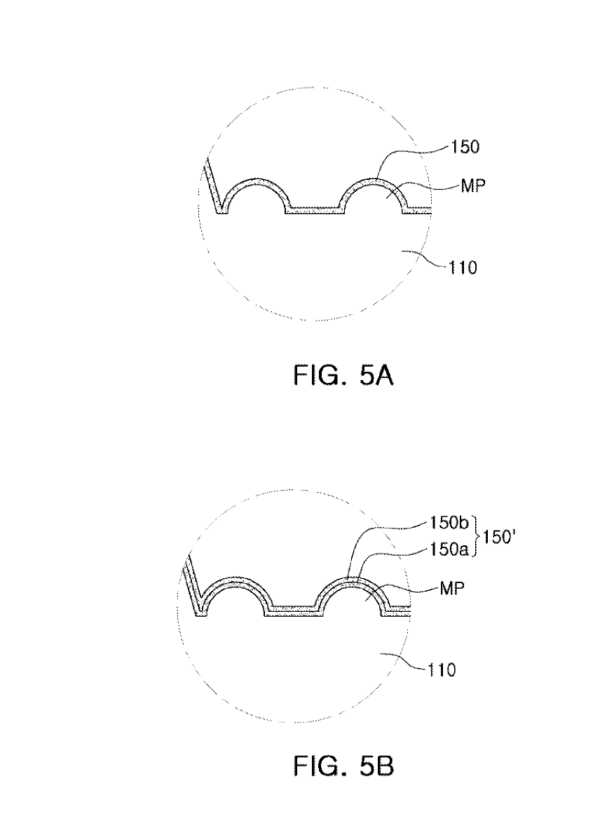

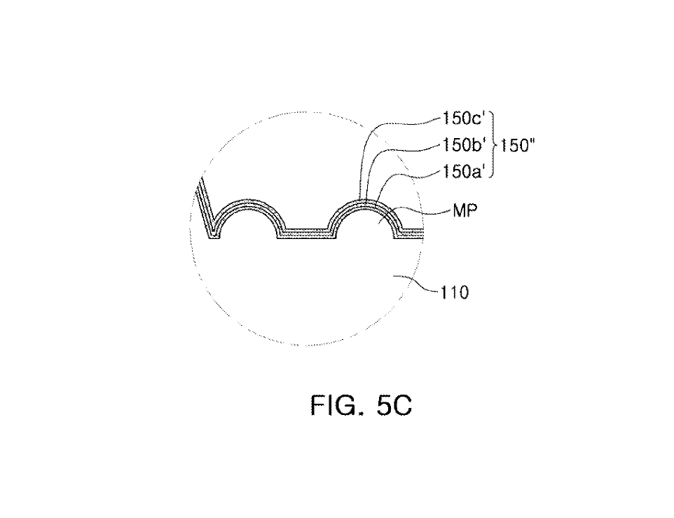

The gradient refractive layer 150 formed on the microstructures MP will be described in detail with reference to FIGS. 5A to 5C.

FIGS. 5A to 5C are enlarged diagrams of area ‘G’ of FIG. 2A.

In example embodiments of the present inventive concepts, referring to FIG. 5A, the gradient refractive layer 150 may be formed of a single material layer. A refractive index of the material layer may be in a range between a refractive index of the first conductivity-type semiconductor layer 110 and a refractive index of silicon oxide. For example, the material layer may be an insulating layer, e.g., Al₂O₃, ZnO, or MgO. A thickness of the material layer may be in the range of 10 nm to 200 nm.

In example embodiments, referring to FIG. 5B, a gradient refractive layer 150′ may be formed of two material layers having different refractive indices. That is, the gradient refractive layer 150′ may be formed of a first gradient refractive layer 150a and a second gradient refractive layer 150b sequentially stacked on the microstructures MP. A refractive index of the first gradient refractive layer 150a may be lower than the refractive index of the first conductivity-type semiconductor layer 110, higher than an encapsulating material, and higher than a refractive index of the second gradient refractive layer 150b. The first and second gradient refractive layers 150a and 150b may be appropriately selected from the insulating materials, e.g., Al₂O₃, ZnO, and MgO, in consideration of refractive indices thereof. Each thickness of the first and second gradient refractive layers 150a and 150b may be in the range of 10 nm to 200 nm.

In example embodiments, referring to FIG. 5C, a gradient refractive layer 150″ may be formed of three material layers having different refractive indices. That is, the gradient refractive layer 150″ may be formed of a first gradient refractive layer 150a′, a second gradient refractive layer 150b′, and a third gradient refractive layer 150c′ sequentially formed on the microstructures MP. A refractive index of the first gradient refractive layer 150a′ may be lower than a refractive index of the first conductivity-type semiconductor layer 110, higher than an encapsulating material and higher than a refractive index of the second gradient refractive layer 150b′. The refractive index of the second gradient refractive layer 150b′ may be lower than that of first gradient refractive layer 150a′, and higher than that of the third gradient refractive layer 150c′. Each thickness of the first, second, and third gradient refractive layer 150a′, 150b′, and 150 c′ may be in the range of 10 nm to 200 nm.

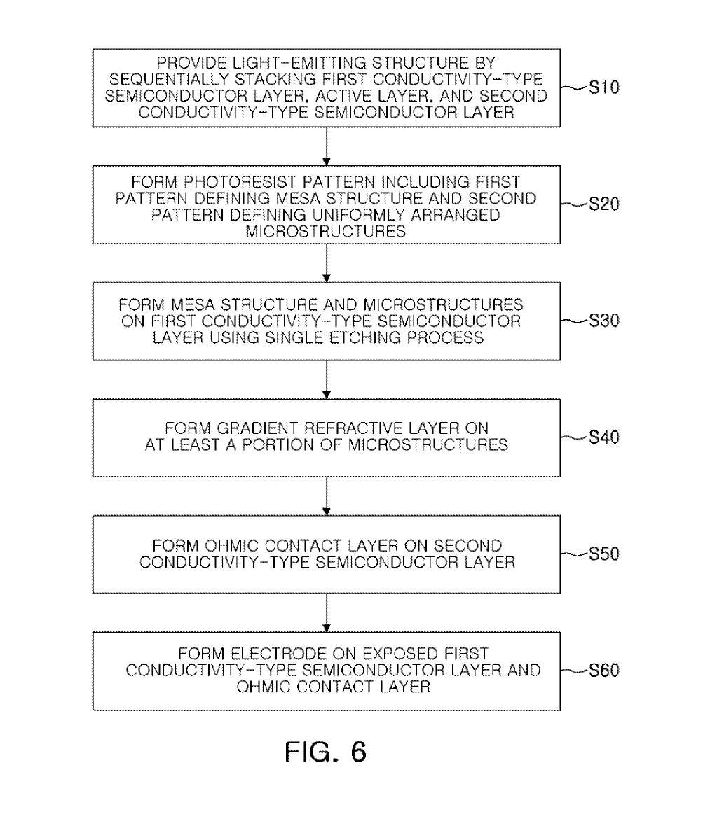

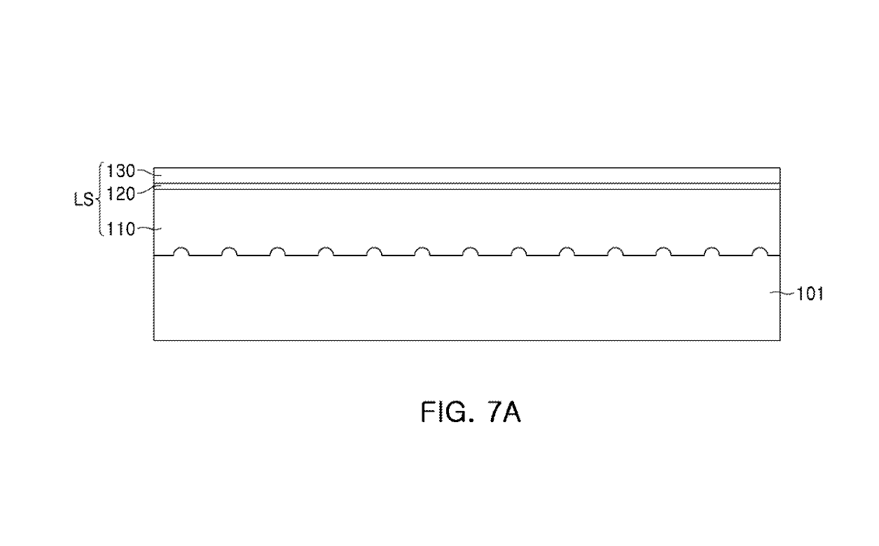

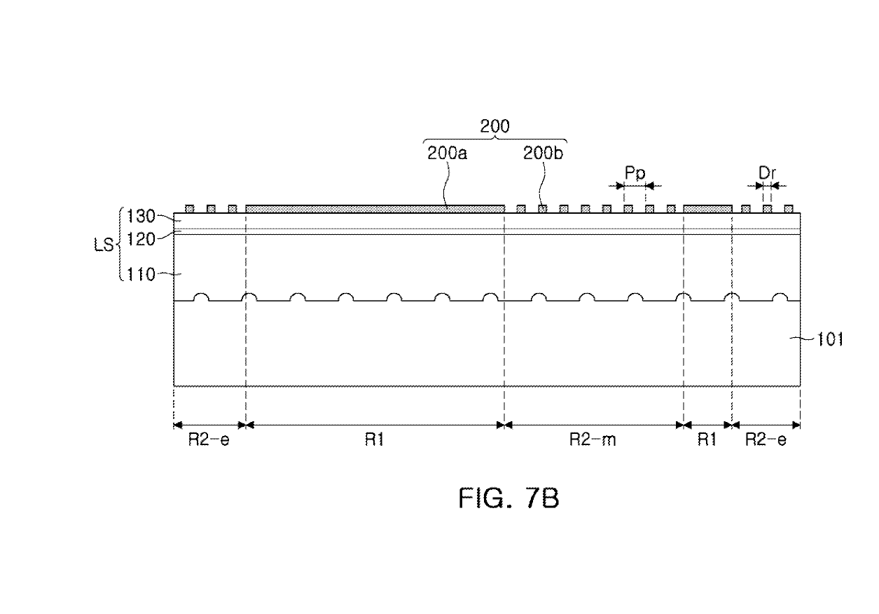

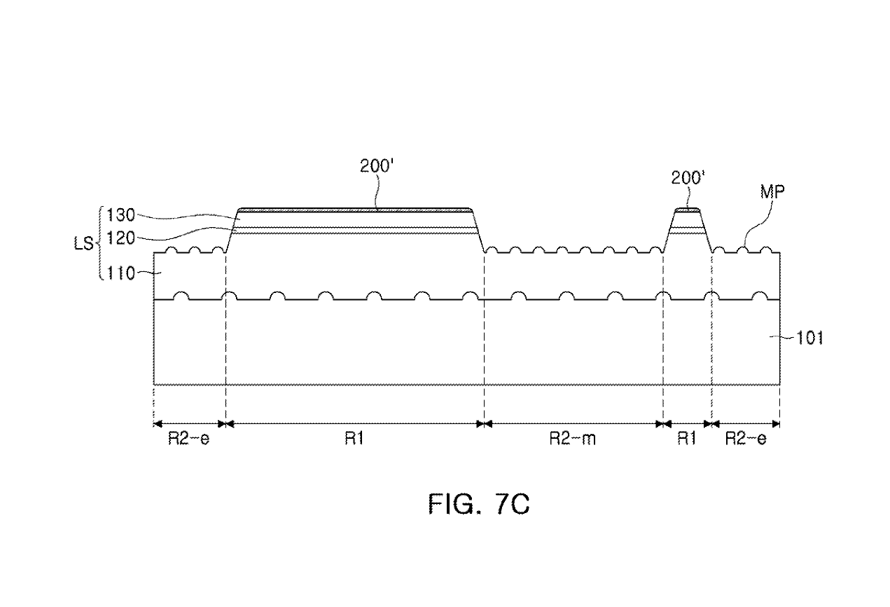

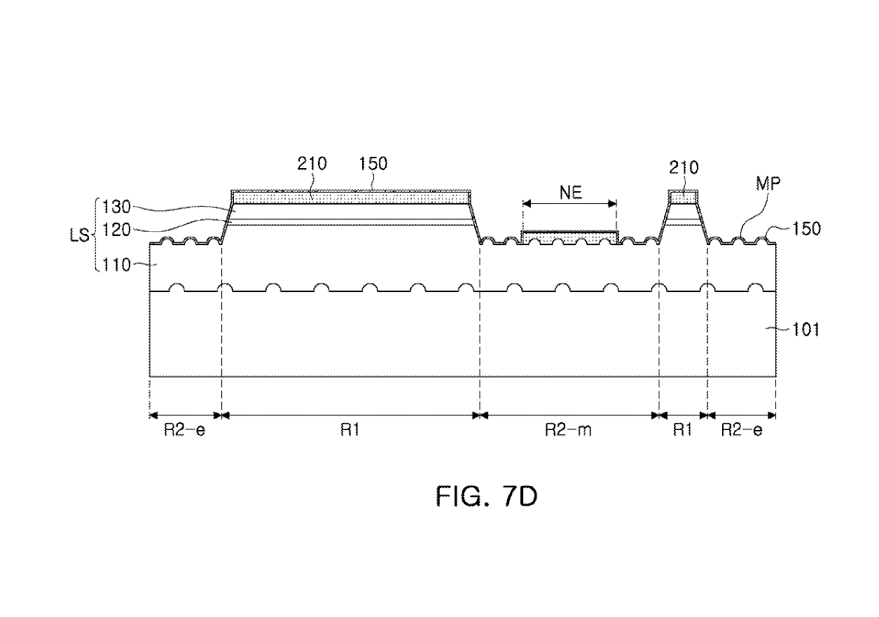

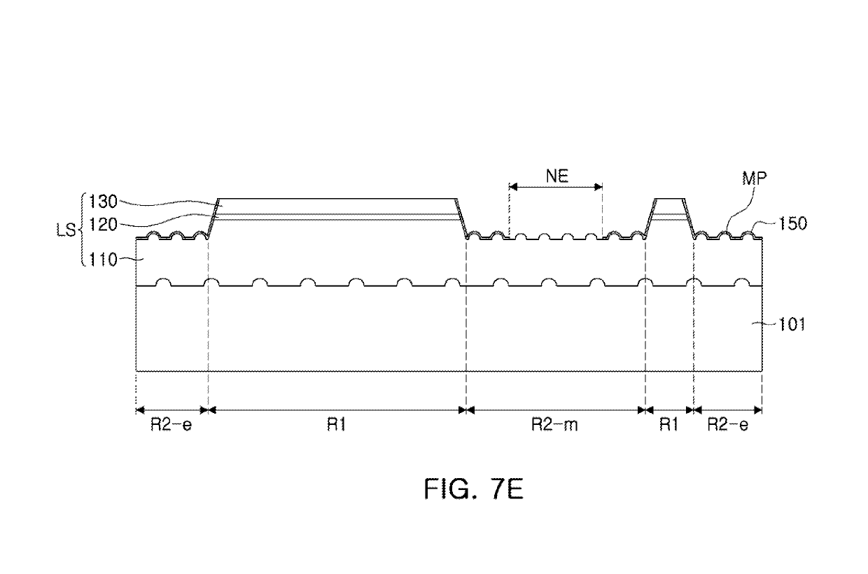

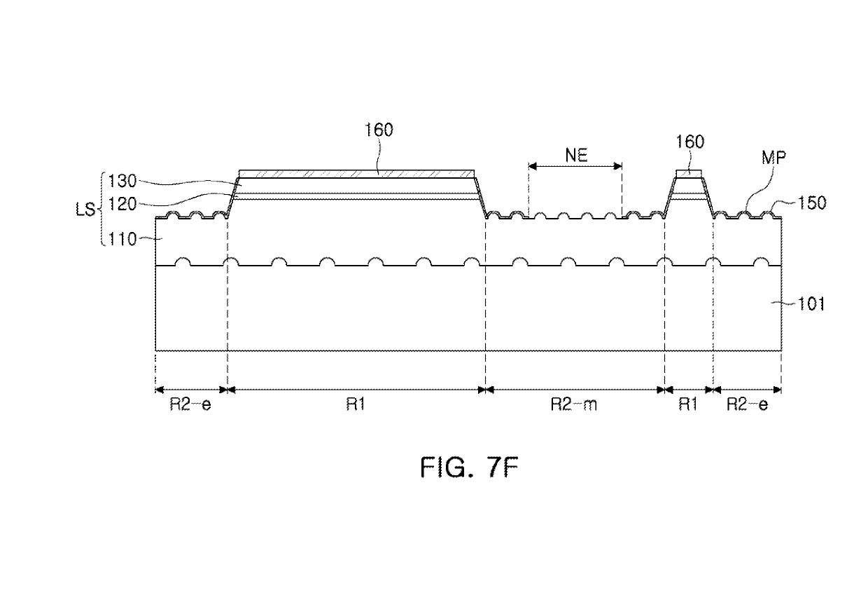

Hereinafter, with reference to FIGS. 7A to 7F together with FIG. 6, a method of manufacturing the above-described semiconductor light-emitting device 10.

FIGS. 7A to 7F are process cross-sectional views of a semiconductor light-emitting device according to example embodiments of the present inventive concepts, and illustrate cross-sections taken along the line A-A′ of the semiconductor light-emitting device illustrated in FIG. 1.

Referring to FIG. 7A together with FIG. 6, a first conductivity-type semiconductor layer 110, an active layer 120, and a second conductivity-type semiconductor layer 130 may be sequentially stacked on a substrate 101 to form a light-emitting structure LS (S10).

The first and second conductivity-type semiconductor layers 110 and 130 and the active layer 120 may be grown using a thin-film growth process, e.g., a metal organic chemical vapor deposition (MOCVD), hydride vapor phase epitaxy (HVPE), or molecular beam epitaxy (MBE).

As illustrated in FIGS. 6 and 7B, a photoresist pattern 200 including a first pattern 200a and a second pattern 200b different from the first pattern 200a may be formed on the light-emitting structure LS using a photolithography process (S20). The first pattern 200a formed on the first region R1 may define a mesa structure, and a second pattern 200b formed on the second region R2 may define microstructures MP regularly arranged with smaller sizes than the mesa structure.

A thickness of the photoresist pattern 200 may be in the range of 2 μm to 3 μm. The second pattern 200b formed on the second region R2 may include micro-patterns in hexagonal lattice pattern arrays or tetragonal lattice pattern arrays as described above with reference to FIGS. 3A, 3B, 4A, and 4B. Each diameter Dr of the microstructures MP may be in the range of 2 μm to 3 μm, and a pitch Pp of the microstructures MP may be in the range of 2.5 μm to 8 μm.

A reflow process may be additionally performed after the photoresist pattern 200 is formed, in order to form the microstructures MP having a shape closer to a hemispherical shape.

Referring to FIGS. 6 and 7, the mesa structure and the microstructures MP may be formed by a single etching process using the photoresist pattern 200 as an etching mask (S30). More specifically, the second conductivity-type semiconductor layer 130 and the active layer 120 may be mesa-etched using the photoresist pattern 200 as the etching mask until the first conductivity-type semiconductor layer 110 is exposed. In general, while the mesa-etching is performed, a certain amount of the photoresist pattern 200 may also be etched. When the mesa-etching is finished, the first pattern 200a may remain on the first region R1, and second pattern 200b may be fully removed on the second region R2. The second pattern 200b including the micro-patterns having a diameter in the range of 2 μm to 3 μm may be etched faster than the first pattern 200a having a large area. Accordingly, the second pattern 200b may be fully etched in the middle of the mesa-etching process. Here, regularly arranged protrusions corresponding to the second pattern 200b may be formed in the second region R2 in which the light-emitting structure LS is partially etched. For example, the protrusions may be formed on the second conductivity-type semiconductor layer 130 exposed by the mesa-etching process. When the mesa-etching is finished, a mesa structure may be formed in the first region R1. In addition, in the second region R2, the protrusions formed on the second conductivity-type semiconductor layer 130 may be transcribed to form the microstructures MP on the first conductivity-type semiconductor layer 110.

The mesa-etching may be an anisotropic etching, and may be performed by a dry etching process, e.g., reactive ion etching or reactive radical etching.

According to example embodiments of the present inventive concepts, the microstructures MP of the first conductivity-type semiconductor layer 110 may be simply and efficiently formed because there is no additional mask formation process and a dry etching or wet etching process after the mesa-etching process.

Because total reflection is reduced due to the microstructures MP of the first conductivity-type semiconductor layer 110, light generated in the active layer 120 may be more easily emitted to an exterior.

Referring to FIGS. 6, 7D and 7E, a gradient refractive layer 150 may be formed on at least a portion of the microstructures MP (S40).

First, as illustrated in FIG. 7D, a photoresist pattern 210 may only be formed in an area on which the gradient refractive layer 150 is not to be formed. More specifically, the photoresist pattern 210 may be formed only on the mesa structure and an area NE on which the first electrode are to be formed. The gradient refractive layer 150 may be formed on the substrate 101 on which the photoresist pattern 210 is formed. A refractive index of the gradient refractive layer 150 may be lower than a refractive index of the first conductivity-type semiconductor layer 110 and higher than a refractive index of silicon oxide (e.g., an encapsulating material). The gradient refractive layer 150 may be formed by sequentially stacking a plurality of material layers having different refractive index. As described above with reference to FIGS. 5A, 5B, and 5C, the refractive index may be gradually decreased toward a top of the plurality of stacked material layers. The material layer may be an insulating layer, e.g., Al₂O₃, ZnO, or MgO.

Referring to FIG. 7E, the photoresist pattern 210 may be removed, and the gradient refractive layer 150 may be formed on the given area of the microstructures. The gradient refractive layer 150 may be formed on sidewalls of the mesa structure. However, the present inventive concepts may not be limited thereto, and in example embodiments, the gradient refractive layer 150 may not be formed on the sidewalls of the mesa structure.

Because a critical angle of total reflection increases due to the gradient refractive layer 150 formed on the microstructures MP of the first conductivity-type semiconductor layer 110, light generated in the active layer 120 may be easily emitted.

Referring to FIGS. 6 and 7F, an ohmic contact layer 160 may be formed on the second conductivity-type semiconductor layer 130 so that a current applied to the second conductivity-type semiconductor layer 130 is uniformed spread (S50). The ohmic contact layer 160 may be formed of at least one selected from the group consisting of ITO, ZnO, ZITO, ZIO, CIO, GIO, ZTO, FTO, AZO, GZO, In₄Sn₃O₁₂, and Zn₍₁₋ₓ₎MgₓO (0≦x≦1).

Referring to FIGS. 2 and 6, a first electrode 170 and a second electrode 180 may be respectively formed on the exposed first conductivity-type semiconductor layer 110 and ohmic contact layer 160 (S60). More specifically, the second electrode 180 may be formed on a predetermined or given area of the ohmic contact layer 160, and the first electrode 170 may be formed on an area of the exposed first conductivity-type semiconductor layer 110, where the gradient refractive layer 150 is not formed.

Thus, a semiconductor light-emitting device 10 including the microstructures MP and having improved light extraction efficiency may be formed on the first conductivity-type semiconductor layer 110.

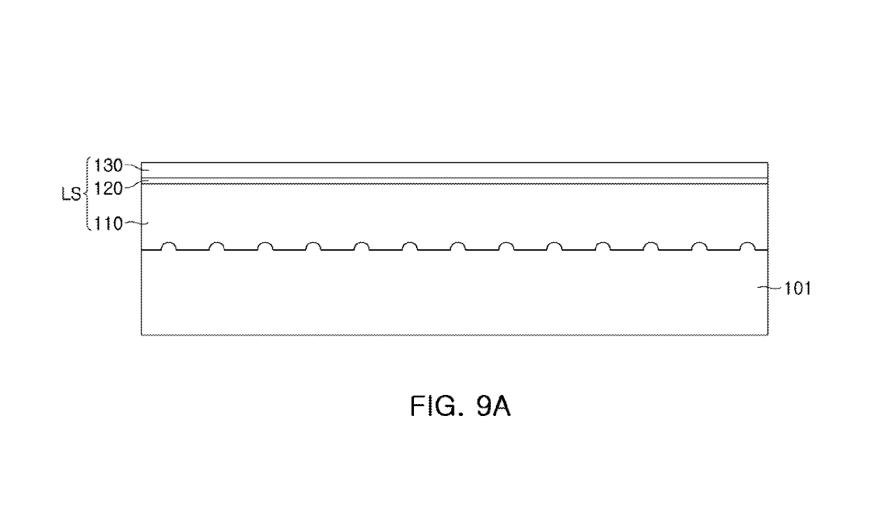

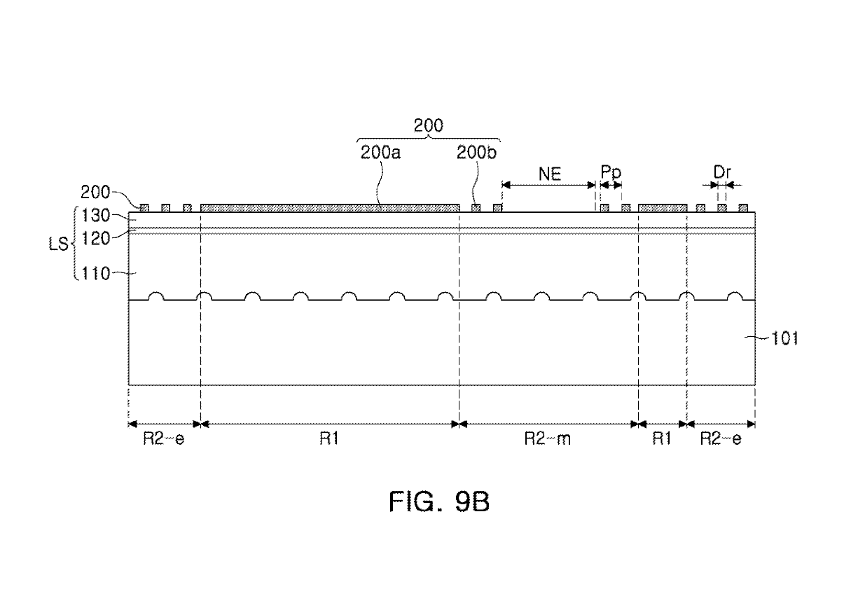

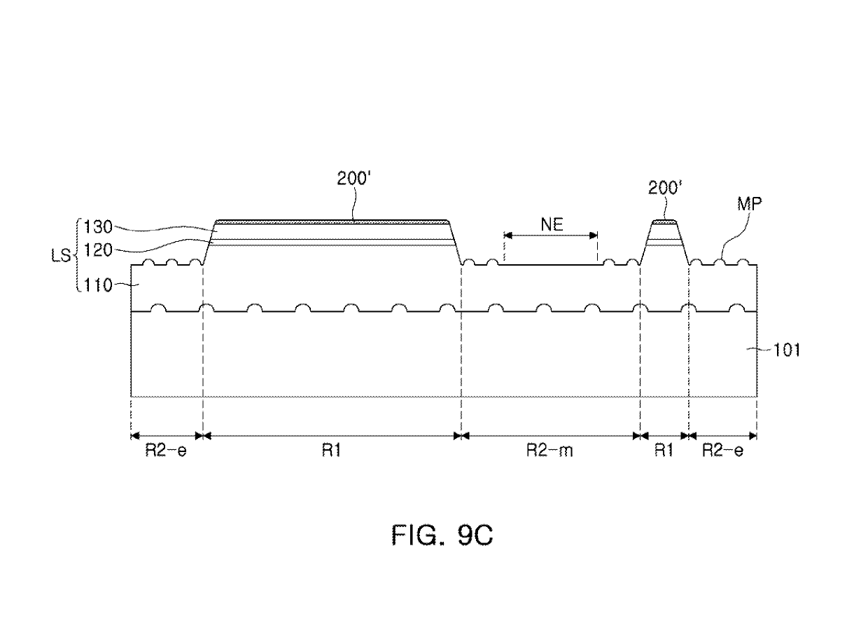

A method of manufacturing a semiconductor light-emitting device according to example embodiments of the present inventive concepts will be described with reference to FIGS. 8 and 9A.

Unlike the semiconductor light-emitting device 10 illustrated in FIG. 2A, a semiconductor light-emitting device 20 illustrated in FIG. 8 may not include microstructures MP on a first conductivity-type semiconductor layer 110 on which a first electrode 170 is formed.

The semiconductor light-emitting device 20 may be divided into a region R1 including a mesa structure, and a region R2 including microstructures MP around the mesa structure. The region R2 including the microstructures MP may be subdivided into a central portion R2-m and an outermost edge portion R2-e. The mesa structure may have a form in which a portion of the first conductivity-type semiconductor layer 110, as well as the second conductivity-type semiconductor layer 130 and the active layer 120 are etched. The microstructures MP may be formed on the first conductivity-type semiconductor layer 110 exposed by mesa-etching. The microstructures MP may be formed of the same material as the first conductivity-type semiconductor layer 110, and a height of the microstructures MP may be lower than a height of an interface of the first conductivity-type semiconductor layer 110 and the active layer 120.

An ohmic contact layer 160 may be formed on the mesa structure, and a second electrode 180 may be disposed on a portion of the ohmic contact layer 160. The first electrode 170 may be formed on a portion of the central portion R2-m in the region R2 including the microstructures MP.

In example embodiments of the present inventive concepts, the microstructures MP may not be formed on an area on which the first electrode 170 is formed. In addition, a gradient refractive layer 150 may be formed on the microstructures MP other than the area on which the first electrode 170 is formed.

Referring to FIGS. 9A and 9B, a first conductivity-type semiconductor layer 110, an active layer 120, and a second conductivity-type semiconductor layer 130 may be sequentially stacked on a substrate 101 to form a light-emitting structure LS, and a photoresist pattern 200 including a first pattern 200a and a second pattern 200b may be formed on the light-emitting structure LS using a photolithography process. The first pattern 200a formed on the first region R1 may define the mesa structure, and the second pattern 200b formed on the second region R2 may define the microstructures MP having a smaller size than the mesa structure and regularly arranged. A pattern defining the microstructures MP may not be formed on an area NE on which the first electrode 170 is to be formed, of the central portion R2-m of the second region R2.

Other features of the photoresist pattern 200 may be the same as those described with reference to FIG. 7B. Accordingly, duplicated descriptions will be omitted.

Referring to FIG. 9C, the mesa structure and the microstructures MP may be formed in a single etching process using the photoresist pattern 200 as an etching mask. The etching process to form the mesa structure and the microstructures MP may be the same as that described with reference to FIG. 3C, Accordingly, duplicated descriptions will be omitted.

However, as illustrated in FIG. 7C, the microstructures MP may not be formed on the first conductivity-type semiconductor layer 110 of area NE on which the first electrode 170 is to be formed.

The semiconductor light-emitting device 20 illustrated in FIG. 8 may be formed by performing the processes described with reference to FIGS. 7D to 7F and forming the first electrode 170 and the second electrode 180 respectively on the first conductivity-type semiconductor layer 110 and the ohmic contact layer 160.

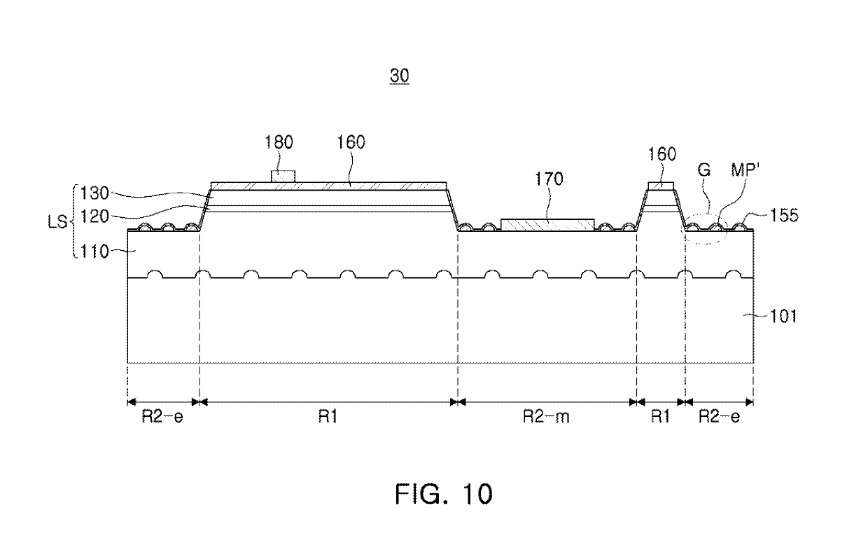

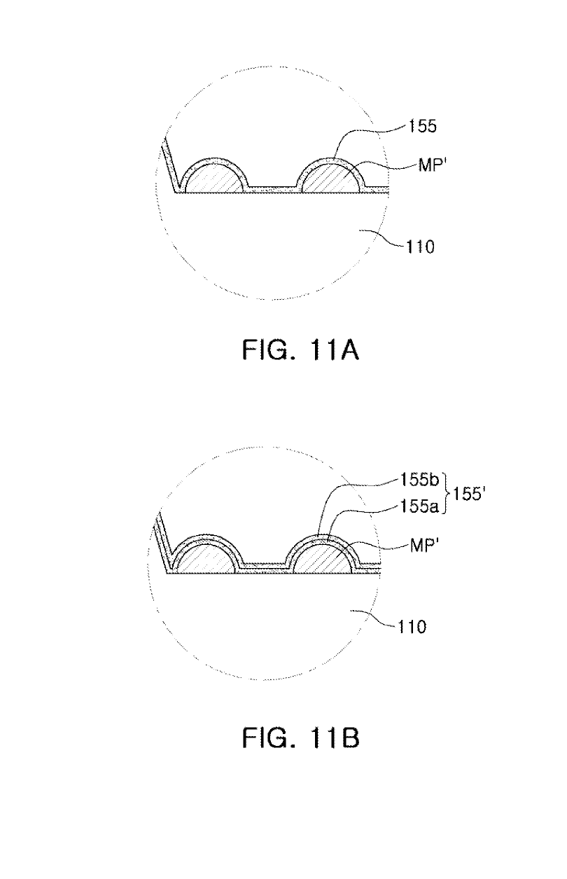

A semiconductor light-emitting device 30 according to example embodiments of the present inventive concepts will be described with reference to FIGS. 10, 11A, and 11B.

Unlike the semiconductor light-emitting device 10 illustrated in FIGS. 2A and 2B, microstructures MP may not be formed on an area of a first conductivity-type semiconductor layer 110 on which a first electrode 170 is formed and the microstructures MP may be formed of a different material from the first conductivity-type semiconductor layer 110, in the semiconductor light-emitting device 30 illustrated in FIG. 10.

The semiconductor light-emitting device 30 may be divided into a region R1 including the mesa structure, and a region R2 including the microstructures MP around the mesa structure. The region R2 including the microstructures MP may be subdivided into a central portion R2-m and an outermost edge portion R2-e. The mesa structure may have a form in which a portion of the first conductivity-type semiconductor layer 110, as well as the second conductivity-type semiconductor layer 130 and the active layer 120 are etched. The microstructures MP may be formed on the first conductivity-type semiconductor layer 110 exposed by mesa-etching. The microstructures MP may be formed of a different material from the first conductivity-type semiconductor layer 110, and a height of the microstructures MP may be lower than a height of an interface of the first conductivity-type semiconductor layer 110 and the active layer 120. The microstructures MP may have a lower refractive index than the first conductivity-type semiconductor layer 110. In example embodiments of the present inventive concepts, the microstructures MP may be formed of ZnO.

An ohmic contact layer 160 may be formed on the mesa structure, and the second electrode 180 may be disposed on a portion of the ohmic contact layer 160. The first electrode 170 may be formed on a portion of the central portion R2-m in the region R2 including the microstructures MP.

In example embodiments of the present inventive concepts, the microstructures may not be formed on an area on which the first electrode 170 is disposed. In addition, a gradient refractive layer 155 may be formed on the microstructures MP other than the area on which the first electrode 170 is disposed.

The gradient refractive layer 155 formed on the microstructures MP will be described with reference to FIGS. 11A and 11B.

FIGS. 11A and 11B are enlarged views of area ‘G’ of FIG. 10.

In example embodiments of the present inventive concepts, referring to FIG. 11A, the gradient refractive layer 155 may be formed of a single material layer. A refractive index of the material layer may be in the range of a refractive index of the first conductivity-type semiconductor layer 110 and a refractive index of silicon oxide. For example, the material layer may be an insulating layer, e.g., Al₂O₃, MgO, or Ta₂O₅. A thickness of the material layer may be in the range of 10 nm to 200 nm.

In example embodiments, referring to FIG. 11B, a gradient refractive layer 155′ may be formed of two material layers having different refractive indices. That is, the gradient refractive layer 155′ may be formed of a first gradient refractive layer 155a and a second gradient refractive layer 155b sequentially stacked on the microstructures MP. A refractive index of the first gradient refractive layer 155a may be lower than the refractive index of microstructures MP and higher than a refractive index of the second gradient refractive layer 155b. For example, the first gradient refractive layer 155a may be MgO, and the second gradient refractive layer 155b may be Al₂O₃. Each thickness of the first and second gradient refractive layers 155a and 155b may be in the range of 10 nm to 200 nm.

The gradient refractive layer may not be limited to the above-described embodiments, and may include three or more material layers having different refractive indices. Those material layers may be arranged such that refractive indices thereof decrease as distances from the first conductivity-type semiconductor layer 110 increase.

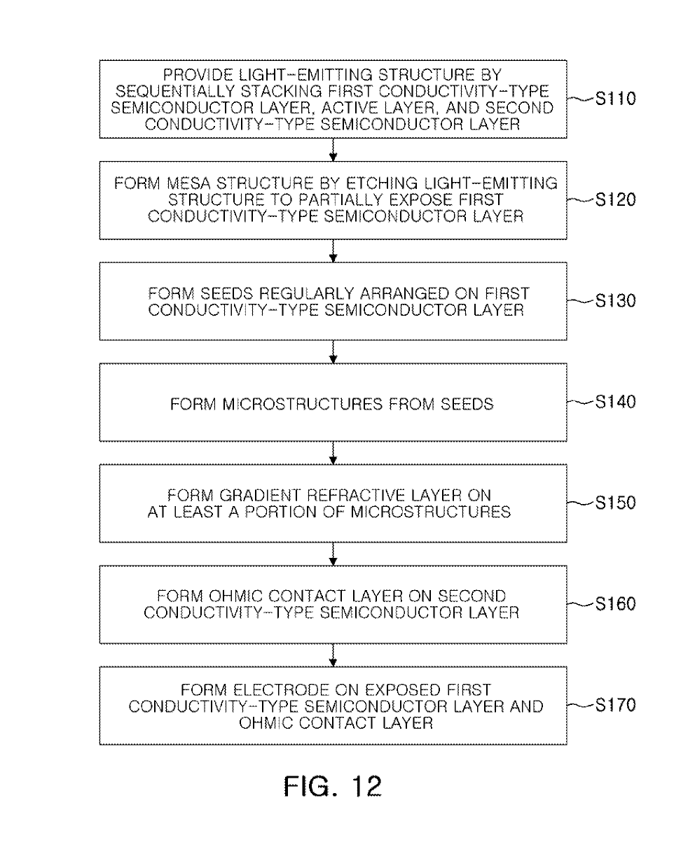

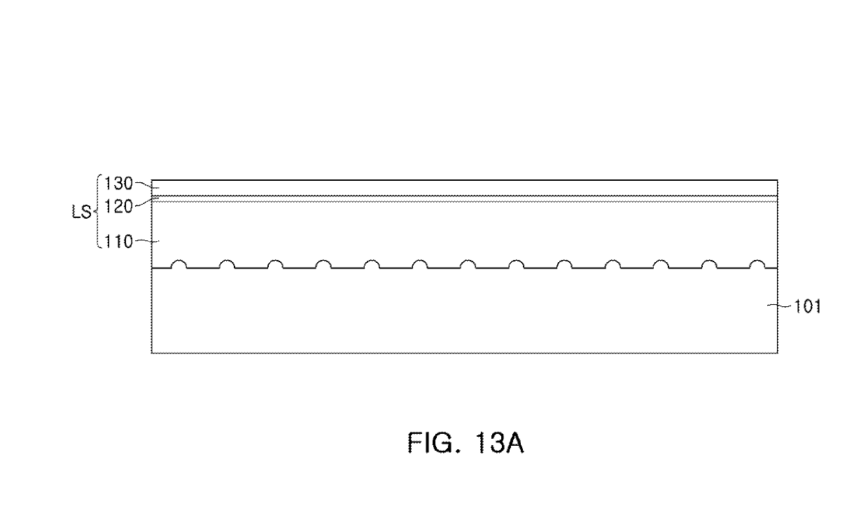

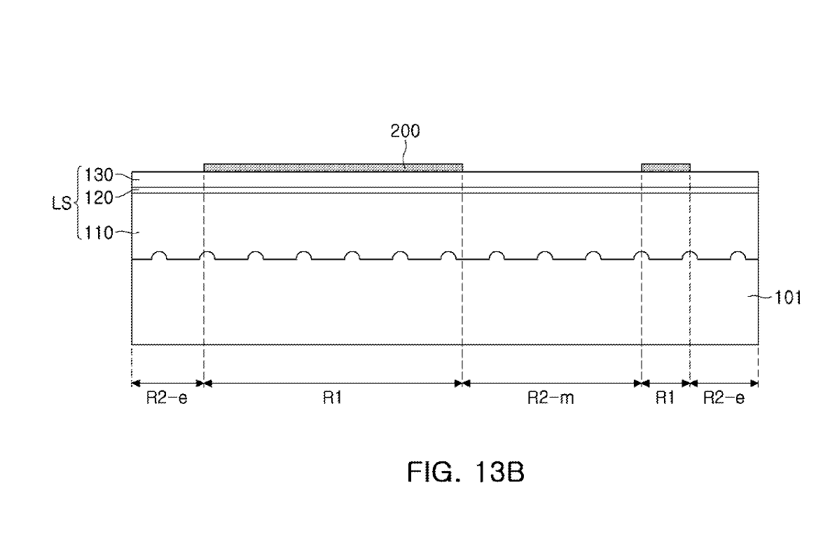

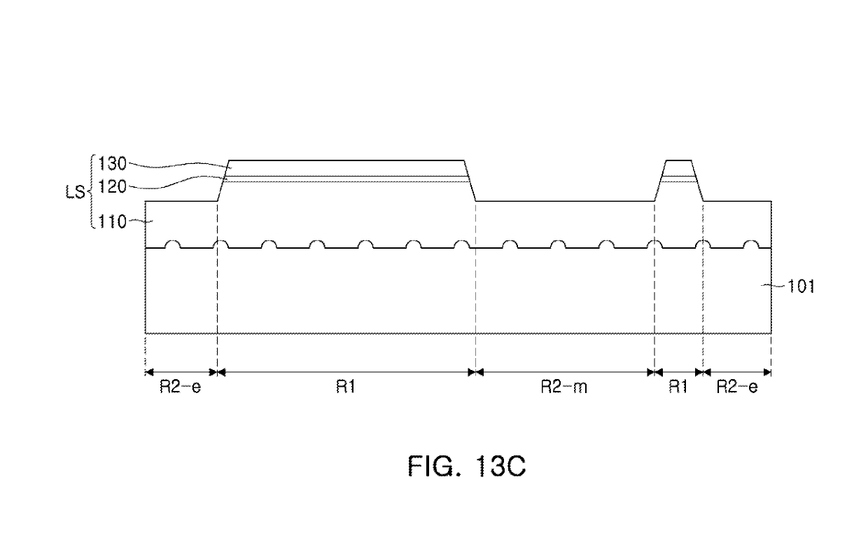

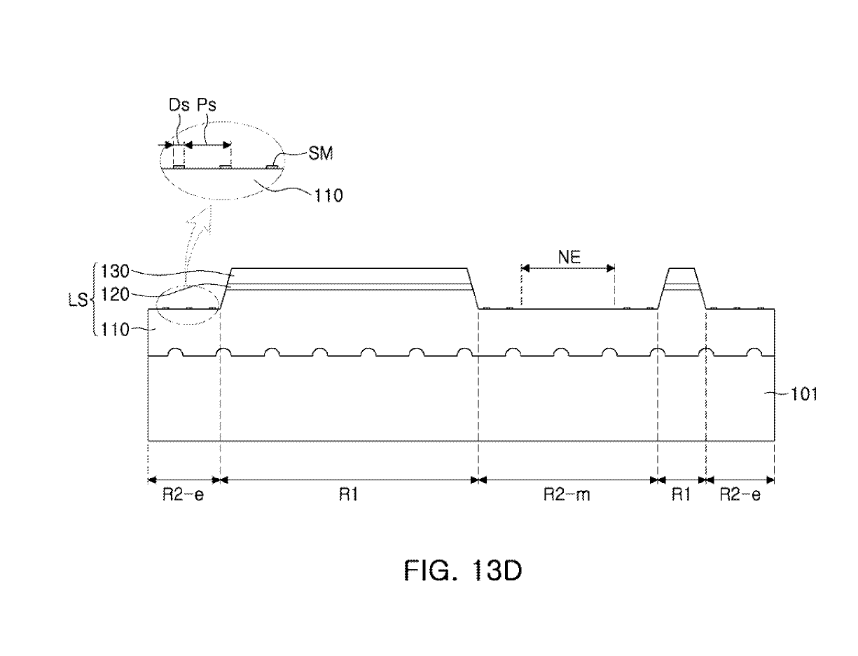

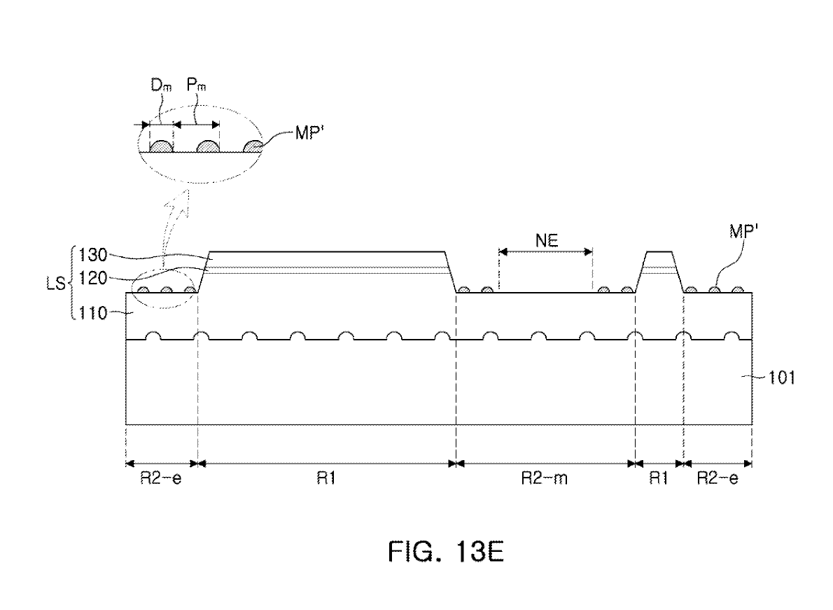

A method of manufacturing the semiconductor light-emitting device 30 illustrated in FIG. 10 according to example embodiments of the present inventive concepts will be described with reference to FIG. 12, and FIGS. 13A to 13E.

Referring to FIGS. 12 and 13A, a first conductivity-type semiconductor layer 110, an active layer 120, and a second conductivity-type semiconductor layer 130 may be sequentially stacked on the substrate 101 to form a light-emitting structure LS (S110).

Referring to FIGS. 12, 13B, and 13C, a photoresist pattern 220 defining a mesa structure may be formed on the light-emitting structure LS using a photolithography and etching process (S120). Accordingly, the light-emitting structure LS may be divided into a first region R1 on which a mesa structure is to be formed and a second region R2 on which microstructures MP are to be formed.

Referring to FIGS. 12-13C, a mesa structure may be formed in the first region R1 by a mesa-etching process using the photoresist pattern 220 as an etching mask. More specifically, the second conductivity-type semiconductor layer 130 and the active layer 120 may be mesa-etched using the photoresist pattern 220 as an etching mask, until the first conductivity-type semiconductor layer 110 is exposed. However, the microstructures MP as illustrated in FIG. 7C may not be formed on the first conductivity-type semiconductor layer 110 exposed by mesa-etching.

The mesa-etching may be an anisotropic etching, and may be performed by a dry etching process, e.g., reactive ion etching or reactive radical etching.

Referring to FIGS. 12 and 13D, a plurality of seeds SM regularly arranged on the first conductivity-type semiconductor layer 110 exposed around the light-emitting structure LS may be formed (S130). Here, the seeds SM may not be formed on an area NE on which the first electrode 170 is to be formed.

The stage S130 of forming the plurality of seeds SM regularly arranged on the first conductivity-type semiconductor layer 110 exposed around the light-emitting structure LS may include forming a patterned mask including cylindrical openings regularly arranged in at least a portion of the first conductivity-type semiconductor layer 110, depositing a seed precursor on the patterned mask, removing the patterned mask, and forming the plurality of seeds SM by oxidizing the seed precursor deposited on the first conductivity-type semiconductor layer 110.

In example embodiments of the present inventive concepts, the patterned mask may be a photoresist pattern formed by a photolithography process. The cylindrical openings may define positions of the microstructures to be formed in a subsequent process and may be regularly arranged in a hexagonal lattice shape or a tetragonal lattice shape. Pitches between the openings may be in the range of 2.5 μm to 8 μm. Meanwhile, diameters of the openings may be smaller than diameters of the finally formed microstructures.

In addition, in example embodiments of the present inventive concepts, the seed precursor may be zinc (Zn), and the deposition of the seed precursor may be performed by e-beam deposition or sputtering at a relatively lower temperature.

When a photoresist is used as the mask, the mask may be removed by a lift-off process using acetone, a base solvent, or the like.

The process of forming the plurality of seeds SMby oxidizing the seed precursor (e.g. Zn) may be performed in a gas phase method or a liquid phase method. In the case of the gas phase method, the seeds SM formed of zinc oxide (ZnO) may be formed by a chemical reaction of the seed precursor (e.g. Zn) with an oxygen gas. In the case of the liquid phase method, the seeds SM formed of ZnO may be formed, using a hydrothermal synthesis method, by applying appropriate conditions, e.g., an appropriate temperature or pressure, to a reaction solution including precursors respectively providing Zn ions and oxygen ions and having at least pH 10 to induce a chemical reaction between the Zn ions and the oxygen ions. The plurality of seeds SM may be regularly arranged in a hexagonal lattice shape and a tetragonal lattice shape. A pitch Ps between the seeds SM may be in the range of 2.5 μm to 8 μm. Meanwhile, diameters Ds of the seeds SM may be smaller than diameters of the microstructures to be finally formed.

Referring to FIGS. 12 and 13E, a plurality of microstructures MP′ may be formed from the plurality of seeds SM (S140). The process may be performed using the hydrothermal synthesis method. That is, first, a plurality of optical waveguide groups may be formed by immersing the light-emitting structure including the plurality of patterned seeds into an immersion solution including precursors providing Zn ions and oxygen ions and having neutrality of about pH 7, and vertically growing the plurality of seeds SM (e.g. growth in c-axis direction) at an appropriate temperature (e.g. in a range of about 50° C. to about 100° C.). Hemispherical microstructures MP′ composed of ZnO may be formed by suppressing the vertical growth of the plurality of optical waveguide groups formed in the above-described process and inducing a lateral volume growth of the plurality of optical waveguide groups. The lateral volume growth may be performed in a second immersion solution including precursors providing Zn ions and oxygen ions at an appropriate temperature (e.g. in a range of about 50° C. to 100° C.). Here, the second immersion solution may be an alkaline solution of about pH 10 or more.

Each diameter Dn of the microstructures MP′ formed on the first conductivity-type semiconductor layer 110 other than an area NE on which the first electrode 170 is to be formed may be in the range of 2 μm to 3 μm, and each height of microstructures MP′ may be lower than a height of an interface between the first conductivity-type semiconductor layer 110 and the active layer 120. The microstructures MP′ may have a hexagonal lattice-shaped array or a tetragonal lattice-shaped array, and a pitch Pp between the microstructures MP′ may be in the range of 2.5 μm to 8 μm.

The manufacturing processes described with reference to FIGS. 7D to 7F (e.g. S150 to S170 in FIG. 12) may be performed, and then a first electrode 170 and a second electrode 180 may be respectively formed on the first conductivity-type semiconductor layer 110 and the ohmic contact layer 160. Thus, the semiconductor light-emitting device 30 illustrated in FIG. 10 may be fabricated.

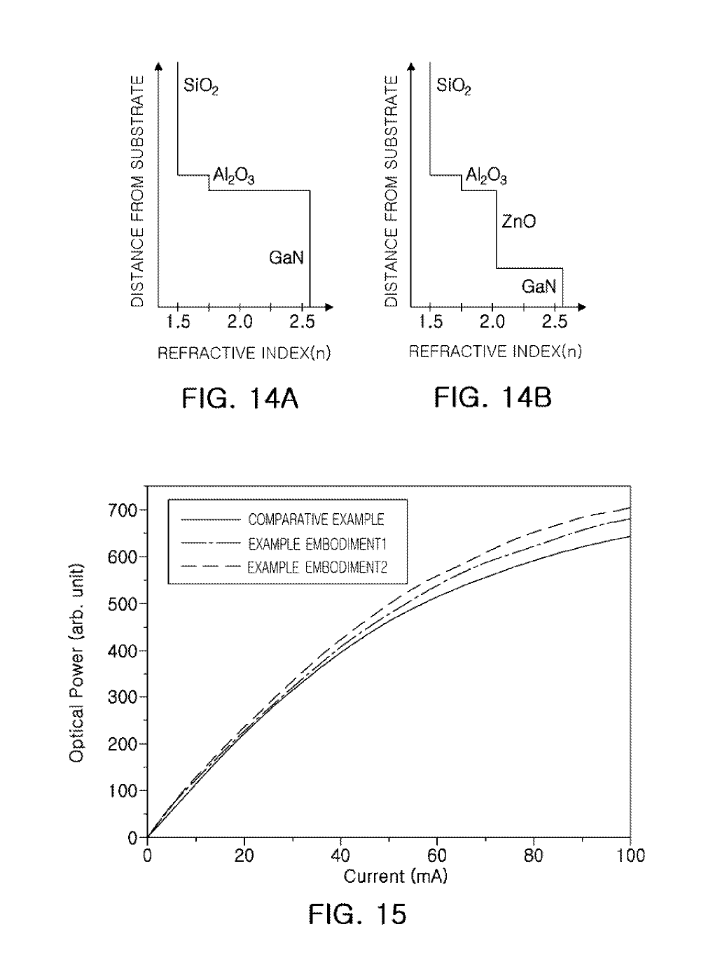

FIGS. 14A and 14B are diagrams illustrating variations in refractive index around microstructures according to example embodiments of the present inventive concepts. FIG. 15 is a graph illustrating light emission efficiency characteristics according to example embodiments of the present inventive concepts.

FIG. 14A depicts variations in refractive index for Example Embodiment 1, and FIG. 14B depicts variations in refractive index for Example Embodiment 2.

Example Embodiment 1 may have the structure of the semiconductor light-emitting device 20 illustrated in FIG. 8. In addition, the first conductivity-type semiconductor layer 110 may be formed of n-type GaN, the microstructures MP formed on the first conductivity-type semiconductor layer 110 may be formed of n-type GaN the same as the first conductivity-type semiconductor layer 110. An Al₂O₃ layer may be disposed as the gradient refractive layer 150 on the microstructures MP. A SiO₂ layer may be understood as being used as an encapsulating material.

Example Embodiment 2 may have the structure of the semiconductor light-emitting device 30 illustrated in FIG. 10. In addition, the first conductivity-type semiconductor layer 110 may be formed of n-type GaN, the microstructures MP′ formed on the first conductivity-type semiconductor layer 110 may be formed of a different material, ZnO, from the first conductivity-type semiconductor layer 110. An Al₂O₃ layer may be disposed as the gradient refractive layer 150 on the microstructures MP. A SiO₂ layer may be understood as being used as an encapsulating material.

In FIG. 5, unlike the semiconductor light-emitting devices illustrated in FIGS. 8 and 10, Comparative Example may be a semiconductor light-emitting device which does not include microstructures and a gradient refractive layer formed on the first conductivity-type semiconductor layer 110. Referring to FIG. 5, as compared with Comparative Example, a light emission efficiency of Example Embodiment 2 may be improved by 3.98% at 20 mA, and light emission efficiency of Example Embodiment 1 may be improved by 1.13% at 20 mA. Due to regularly arranged microstructures formed on the first conductivity-type semiconductor layer exposed around the light-emitting structure having a mesa structure, and a gradient refractive layer formed on the microstructures, a light emission efficiency of the semiconductor light-emitting device may be improved.

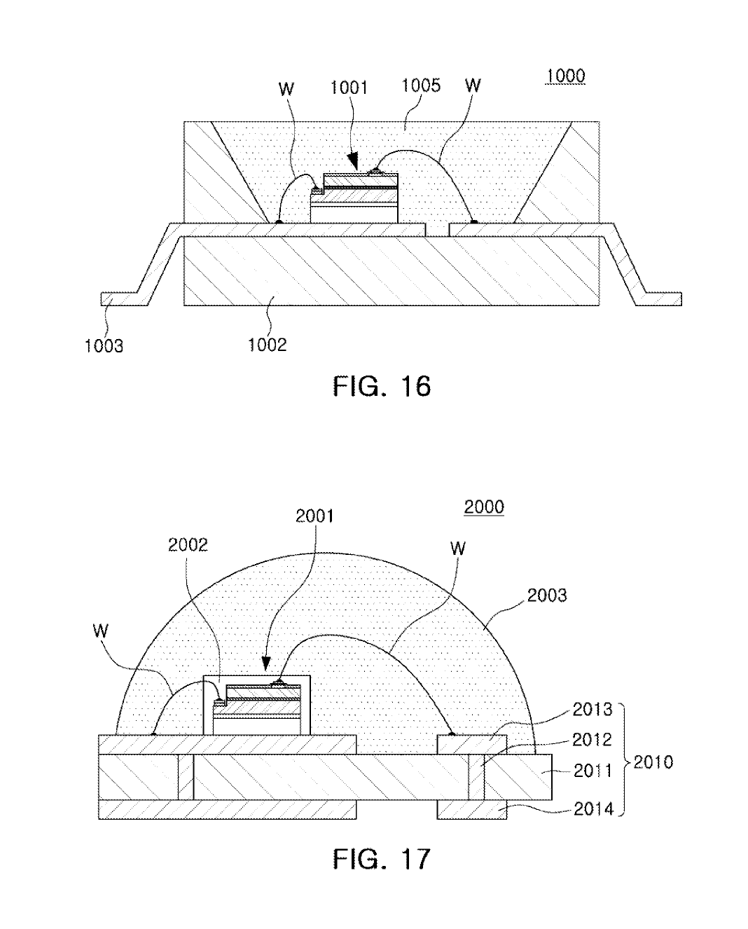

FIGS. 16 and 17 illustrate examples in which a semiconductor light-emitting device fabricated according to example embodiments of the present inventive concepts is applied to a package.

Referring to FIG. 16, a light-emitting device package 1000 may include a semiconductor light-emitting device 1001, a package body 1002, and a pair of lead frames 1003. The semiconductor light-emitting device 1001 may be mounted on the lead frames 1003 and electrically connected to the lead frame 1003 through wires W. In example embodiments, the semiconductor light-emitting device 1001 may be mounted on an area other than the lead frame 1003. For example, the semiconductor light-emitting device 1001 may be mounted on the package body 1002. In addition, the package body 1002 may include a reflective cup in order to improve light reflection efficiency. An encapsulating layer 1005 formed of a light-transmissive material may be disposed in the reflective cup in order to encapsulate the semiconductor light-emitting device 1001 and the wires W. The light-emitting device package 1000 may include a semiconductor light-emitting device fabricated according to the above-described example embodiments of the present inventive concepts. In example embodiments, the package body 1002 and/or the encapsulating layer 1005 may be formed of a material having a black hue. As needed, the package body 1002 and/or the encapsulating layer 1005 may be formed to appear black by coating an upper surface of the package body 1002 with a black material. Such a black package may be utilized in a display, e.g., an electronic display board.

In example embodiments, a package formed by molding a semiconductor light-emitting device mounted on a board, e.g., a PCB, with a transparent black resin may be utilized in a display, e.g., an electronic display board.

The black-colored package may include a blue light-emitting device, a green light-emitting device, and/or a red light-emitting device, having a structure of a light-emitting device according to example embodiments of the present inventive concepts.

Referring to FIG. 17, a light-emitting device package 2000 may include a semiconductor light-emitting device 2001, a mounting board 2010, and an encapsulating material 2003. In addition, a wavelength conversion layer 2002 may be formed on a surface and/or a side surface of the semiconductor light-emitting device 2001. The semiconductor light-emitting device 2001 may be mounted on the mounting board 2010 and electrically connected to the mounting board 2010 through wires W or flip-chip bonding.

The mounting board 2010 may include a board body 2011, an upper surface electrode 2013, and a lower surface electrode 2014. In addition, the mounting board 2010 may include a through electrode 2012 connecting the upper surface electrode 2013 and a lower surface electrode 2014. The mounting board 2010 may be provided as a board, e.g., a PCB, an MCPCB, an MPCB, or an FPCB, and a structure of the mounting board 2010 may be applied in various forms.

When the semiconductor light-emitting device 2001 of the light-emitting device package 2000 according to example embodiments of the present inventive concepts emits UV light or blue light, the wavelength conversion layer 2002 may include at least one of blue, yellow, green, and red fluorescent materials, and allow white light or yellow, green, or red light to be emitted through a combination of the blue light generated by the semiconductor light-emitting device 2001 and light generated by the fluorescent materials. A color temperature and a color rendering index (CRI) of the white light may be controlled using a light-emitting module emitting white light, formed by combination of a light-emitting device package emitting white light and a light-emitting device package emitting yellow, green, or red light. In addition, the light-emitting device packages may be configured to include at least one light-emitting device emitting violet, blue, green, red, and UV light. In example embodiments, a color rendering index (CRI) of the light-emitting device package or the light-emitting module formed by combination of the light-emitting device packages may be controlled in the range from a level of CRI 40 to a level of solar light (CRI 100), and a variety of levels of white light having a color temperature in the range of 2,000K to 20,000K may be generated. In addition, as needed, the light-emitting device package 2000 may generate visible light having a purple, blue, green, red, or orange color, or infrared light, and control the color according to an environment or mood. In addition, the light-emitting device package 2000 may emit light having a specific wavelength to promote plant growth.

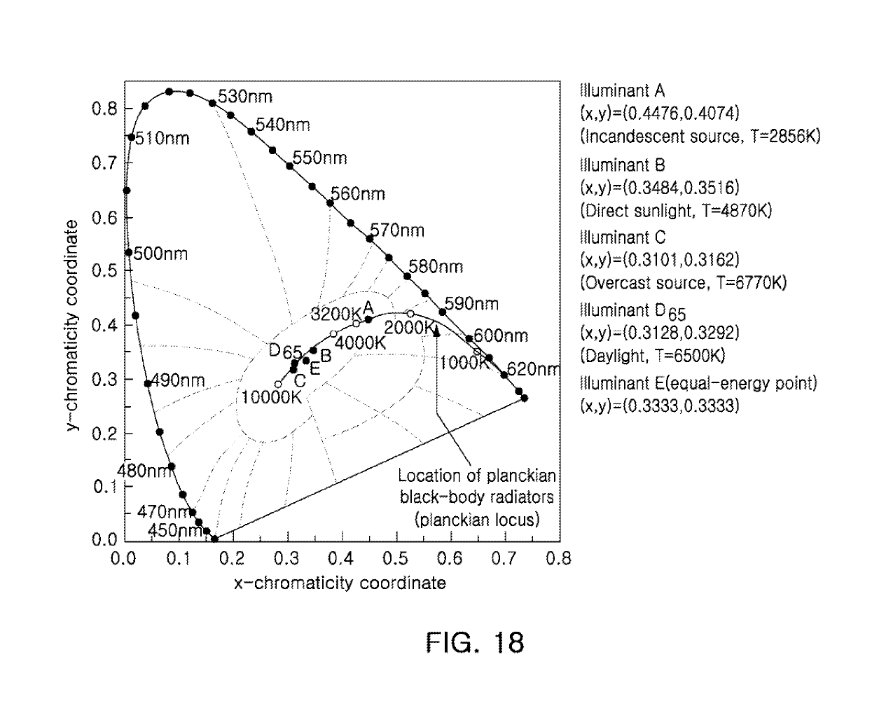

White light formed by combination of the UV or blue light-emitting device, and yellow, green, and red fluorescent materials and/or green and red light-emitting devices may have two or more peak wavelengths, and may be located on the line connecting (x, y) coordinates of (0.4476, 0.4074), (0.3484, 0.3516), (0.3101, 0.3162), (0.3128, 0.3292), (0.3333, 0.3333) in the CIE 1931 coordinate system illustrated in FIG. 18. Otherwise, the white light may be located in a zone surrounded by the line and a black body radiation spectrum. The color temperature of the white light may corresponds to 2,000K to 20,000K.

The wavelength conversion layer 2002 may include a fluorescent material or quantum dots.

The fluorescent material may have a compositional formula and color as follows.

Oxide group: yellow and green Y₃Al₅O₁₂:Ce, Tb₃Al₅O₁₂:Ce, Lu₃Al₅O₁₂:Ce

Silicate group: yellow and green (Ba,Sr)₂SiO₄:Eu, yellow and orange (Ba,Sr)₃SiO₅:Ce

Nitride group: green β-SiAlON:Eu, yellow La₃Si₆N₁₁:Ce, orange α-SiAlON:Eu, red CaAlSiN₃:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}Al_{y}O_{3+x+y}N_{18-x-y} (0.5≦x≦3, 0<z<0.3, and 0<y≦4) (Here, Ln is at least one element selected from the group consisting of a Group IIIa element and a rare earth element, and M is at least one element selected from the group consisting of Ca, Ba, Sr, and Mg.)

Fluoride group: KSF-based red K₂SiF₆:Mn⁴⁺, K₂TiF₆:Mn⁴⁺, NaYF₄:Mn⁴⁺, NaGdF₄:Mn⁴⁺

The composition of the fluorescent material may be basically stoichiometric and each element may be substituted by another element within a corresponding group on the periodic table. For example, Sr may be substituted by Ba, Ca, or Mg in the alkaline-earth (II) group, and Y may be substituted by Tb, Lu, Sc, or Gd in the lanthanide group. In addition, an activator, Eu, may be substituted by Ce, Tb, Pr, Er, or Yb depending on a given energy level. The activator may be used alone, or a co-activator may be additionally used to change characteristics thereof.

In addition, a quantum dot may replace the fluorescent material, or the fluorescent material and the quantum dot may be used alone or as a mixture thereof.

The quantum dot may have a structure consisting of a core (e.g., CdSe or InP (3 to 10 nm)), a shell (e.g., ZnS or ZnSe (0.5 to 2 nm)), and a ligand for stabilizing the core and the shell. In addition, the quantum dot may implement a variety of colors according to a size thereof.

The following Table 1 illustrates various types of fluorescent materials of a white light-emitting device package using a UV light-emitting device chip (200 nm to 440 nm) or a blue light-emitting device chip (440 nm to 480 nm), listed by applications.

TABLE 1

| Purpose | Fluorescent Material |
|---|---|
| LED TV BLU | β-SiAlON: Eu²⁺, (Ca,Sr)AlSiN₃: Eu²⁺, La₃Si₆N₁₁: Ce³⁺, |
| | K₂SiF₆: Mn⁴⁺, SrLiAl₃N₄: Eu, Ln₄₋ₓ (Eu_{z}M_{1-z})ₓSi_{12-y}Al_{y}O_{3+x+y}N_{18-x-y} |
| | (0.5 ≦ x ≦ 3, 0 < z < 0.3, and 0 < y ≦ 4), K₂TiF₆: Mn⁴⁺, NaYF₄: Mn⁴⁺, |
| | NaGdF₄: Mn⁴⁺ |
| Illuminations | Lu₃Al₅O₁₂: Ce³⁺, Ca-α-SiAlON: Eu²⁺, La₃Si₆N₁₁: Ce³⁺, (Ca, |
| | Sr)AlSiN₃: Eu²⁺, Y₃Al₅O₁₂: Ce³⁺, K₂SiF₆: Mn⁴⁺, SrLiAl₃N₄: Eu, |
| | Ln₄₋ₓ(Eu_{z}M_{1-z})ₓSi_{12-y}Al_{y}O_{3+x+y}N_{18-x-y}(0.5 ≦ x ≦ 3, 0 < z < 0.3, and |
| | 0 < y ≦ 4), K₂TiF₆: Mn⁴⁺, NaYF₄: Mn⁴⁺, NaGdF₄: Mn⁴⁺ |
| Side View | Lu₃Al₅O₁₂: Ce³⁺, Ca-α-SiAlON: Eu²⁺, La₃Si₆N₁₁: Ce³⁺, (Ca, |
| (Mobile, | Sr)AlSiN₃: Eu²⁺, Y₃Al₅O₁₂: Ce³⁺, (Sr, Ba, Ca, Mg)₂SiO₄: Eu²⁺, |
| Note PC) | K₂SiF₆: Mn⁴⁺, SrLiAl₃N₄: Eu, |
| | Ln₄₋ₓ(Eu_{z}M_{1-z})ₓSi_{12-y}Al_{y}O_{3+x+y}N_{18-x-y}(0.5 ≦ x ≦ 3, 0 < z < 0.3, and |
| | 0 < y ≦ 4), K₂TiF₆: Mn⁴⁺, NaYF₄: Mn⁴⁺, NaGdF₄: Mn⁴⁺ |
| Electronics | Lu₃Al₅O₁₂: Ce³⁺, Ca-α-SiAlON: Eu²⁺, La₃Si₆N₁₁: Ce³⁺, (Ca, |
| (Head Lamp, | Sr)AlSiN₃: Eu²⁺, Y₃Al₅O₁₂: Ce³⁺, K₂SiF₆: Mn⁴⁺, SrLiAl₃N₄: Eu, |
| etc.) | Ln₄₋ₓ(Eu_{z}M_{1-z})ₓSi_{12-y}Al_{y}O_{3+x+y}N_{18-x-y} (0.5 ≦ x ≦ 3, 0 < z < 0.3, and |
| | 0 < y ≦ 4), K₂TiF₆: Mn⁴⁺, NaYF₄: Mn⁴⁺, NaGdF₄: Mn⁴⁺ |

The encapsulating material 2003 may have a dome-shaped lens structure having a convex upper surface. In example embodiments, the encapsulating material 2003 may have a convex or concave lens structure to adjust a beam angle of light emitted through an upper surface of the encapsulating material 2003.

In example embodiments of the present inventive concepts, the light-emitting device package 2000 may include the semiconductor light-emitting device described in example embodiments of the present inventive concepts.

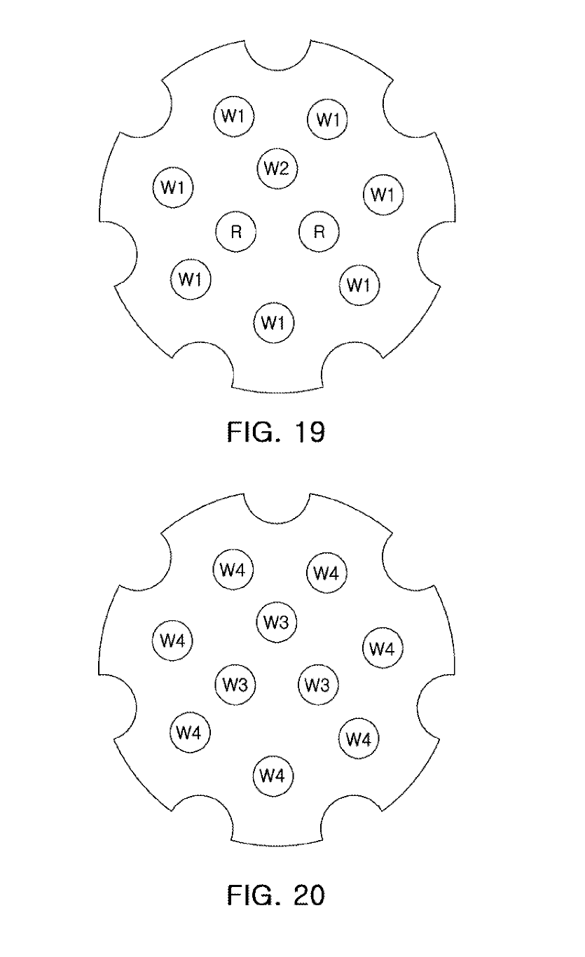

FIGS. 19 and 20 illustrate light source modules to which a semiconductor light-emitting device fabricated according to example embodiments of the present inventive concepts is applied.

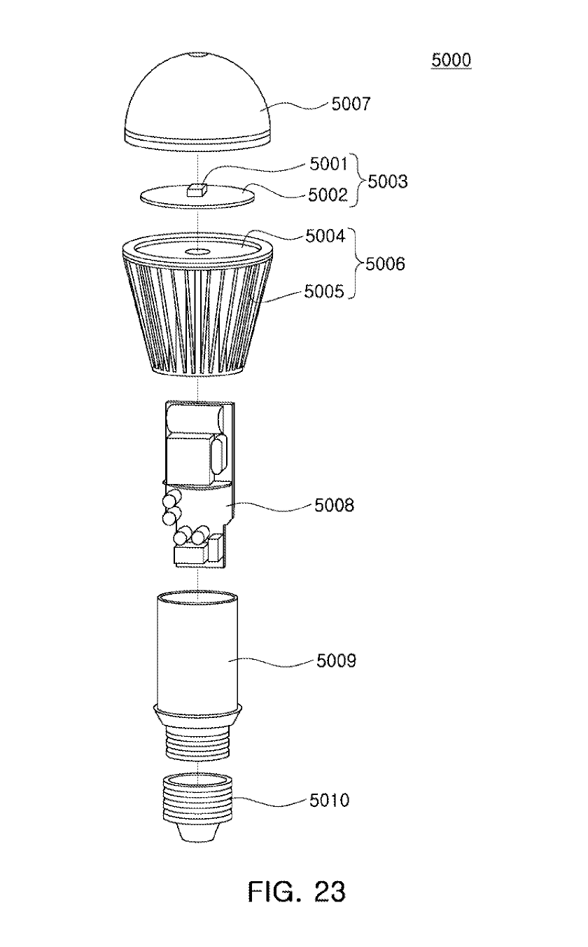

Referring to FIG. 19, a white light-emitting device package W1 having a color temperature of 4,000K, a white light-emitting device package W2 having a color temperature of 3,000K, and a red light-emitting device package R may be disposed in a white light-emitting package module. The color temperature of the white light-emitting package module may be controlled to be within the range of 2,000K to 4,000K by combining the light-emitting device packages. In addition, a white light-emitting package module having a CRI Ra of 85 to 99 may be fabricated. Such a light source module may be utilized in a bulb-type lamp illustrated in FIG. 23.

Referring to FIG. 20, a white light-emitting device package W3 having a color temperature of 5,000K and a white light-emitting device package W4 having a color temperature of 2,700K may be disposed in a white light-emitting package module. The color temperature of the white light-emitting package module may be controlled to be within the range of 2,700K to 5,000K by combining the light-emitting device packages. In addition, a white light-emitting package module having a CRI Ra of 85 to 99 may be fabricated. Such a white light-emitting package module may be utilized in a bulb-type lamp, which will be illustrated in FIG. 23.

The number of the light-emitting device packages may differ according to basic color temperature settings. When the basic color temperature settings are 4,000K, the number of light-emitting device packages corresponding to a color temperature of 4,000K may be more than the number of light-emitting device packages corresponding to a color temperature of 3,000K or the number of red light-emitting device packages.

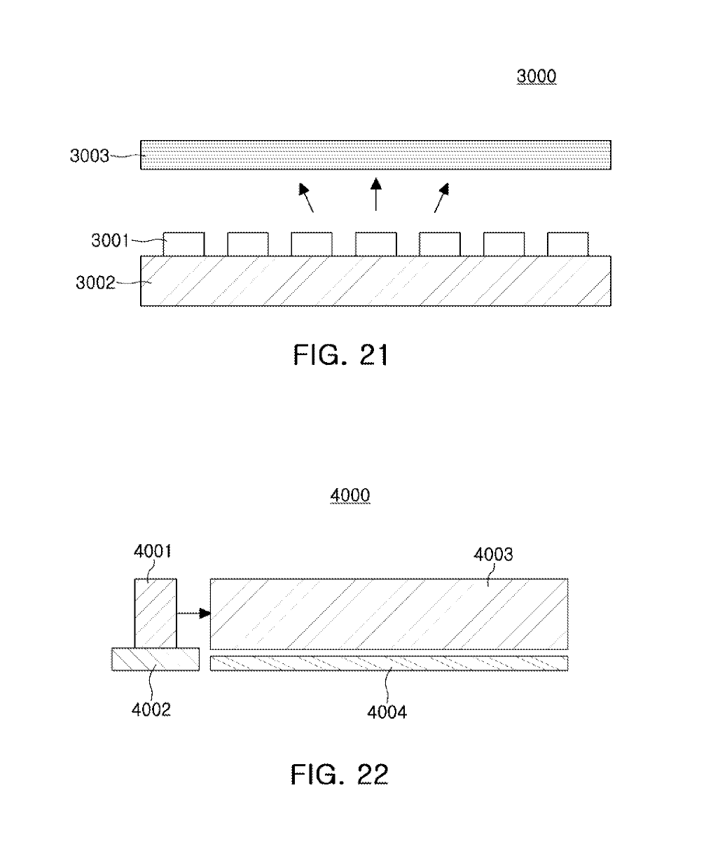

FIGS. 21 and 22 illustrate examples in which a semiconductor light-emitting device fabricated according to example embodiments of the present inventive concepts is applied to a backlight unit.

Referring to FIG. 21, a backlight unit 3000 may include a light source 3001 mounted on a substrate 3002, and one or more optical sheets 3003 disposed on the light source 3001. The light source 3001 may be provided in a chip-on-board type (a so called COB type) in which the above-described semiconductor light-emitting device may be directly mounted on the substrate 3002, or may use the semiconductor light-emitting device package described with reference to FIGS. 16 and 17.

The light source 3001 in the backlight unit 3000 illustrated in FIG. 21 emits light toward a top surface where a liquid crystal display (LCD) is disposed. On the contrary, in another backlight unit 4000 illustrated in FIG. 22, a light source 4001 mounted on a substrate 4002 emits light in a lateral direction, and the emitted light may be incident to a light guide plate 4003 and converted to the form of surface light source. Light passing through the light guide plate 4003 is emitted upwardly, and a reflective layer 4004 may be disposed on a bottom surface of the light guide plate 4003 to improve light extraction efficiency.

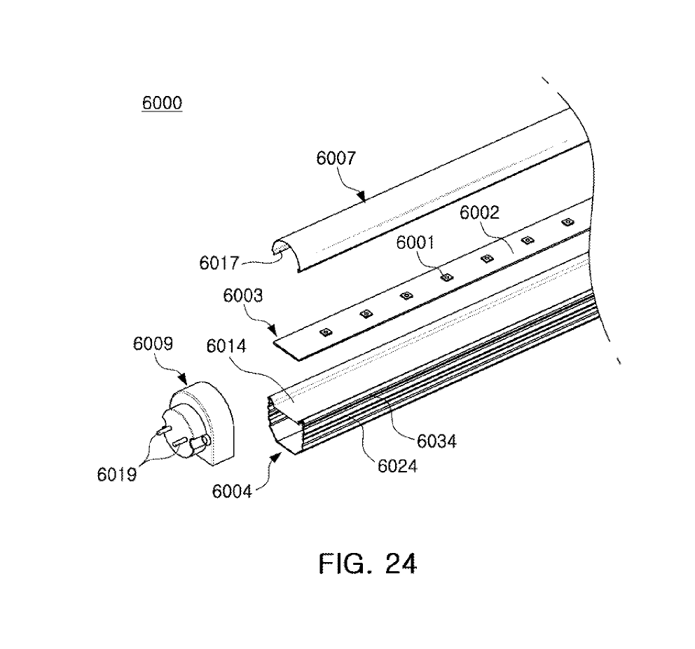

FIGS. 23 and 24 illustrate examples in which a semiconductor light-emitting device according to example embodiments of the present inventive concepts is applied to a lighting apparatus.

Referring to an exploded perspective view of FIG. 23, a lighting apparatus 5000 is illustrated as a bulb-type lamp as an example, and includes a light-emitting module 5003, a driver 5008, and an external connection portion 5010. In addition, external structures, e.g., external and internal housings 5006 and 5009 and a cover 5007, may be further included. The light-emitting module 5003 may include a light source 5001 and a circuit board 5002 with the light source 5001 mounted thereon. As the light source 5001, the semiconductor light-emitting device described in the above-described example embodiments of the present inventive concepts, or a light-emitting device package may be used.

In example embodiments of the present inventive concepts, a single light source 5001 is mounted on the circuit board 5002, but a plurality of light sources 5001 may be mounted as needed.

In addition, the light-emitting module 5003 may include the external housing 5006 which acts as a heat dissipating unit, and the external housing 5006 may include a heat dissipation plate 5004 in direct contact with the light-emitting module 5003 to enhance a heat dissipation effect. In addition, the lighting apparatus 5000 may include the cover 5007 installed on the light-emitting module 5003 and having a convex lens shape. The driver 5008 may be installed in the internal housing 5009 and connected to the external connection portion 5010, e.g., a socket structure, to receive power from an external power source. In addition, the driver 5008 may function to convert the power to an appropriate current source capable of driving the semiconductor light-emitting device 5011 of the light-emitting module 5003. For example, the driver 5008 may be configured as an AC-DC converter, a rectifying circuit component, or the like.

Meanwhile the lighting apparatus including a light source device according to example embodiments of the present inventive concepts may be a bar-type lamp as illustrated in FIG. 24. Although not illustrated in the drawings, a lighting apparatus according to example embodiments of the present inventive concepts may have a similar shape to a fluorescent lamp so as to replace conventional fluorescent lamps, an may emit light having similar optical characteristics to the fluorescent lamp.

Referring to an explosive perspective view of FIG. 24, a lighting apparatus 6000 according to example embodiments of the present inventive concepts may include a light source unit 6203, a body 6204, and a driving unit 6209. In addition, the lighting apparatus 6000 according to example embodiments of the present inventive concepts may further include a cover 6207 covering the light source unit 6203.

The light source unit 6203 may include a substrate 6202, and a plurality of light sources 6201 mounted on the substrate 6202. As the light sources 6201, the semiconductor light emitting device or the light-emitting device package described above in example embodiments of the present inventive concepts may be used.

The light source unit 6203 may be fixedly mounted on a surface of the body 6204. The body 6204 may be a kind of a supporting structure and include a heat sink. The body 6204 may be formed of a material having high thermal conductivity, for example, a metal, in order to release heat generated in the light source unit 6203 to the outside, but is not limited thereto.

The body 6204 may have an elongated rod shape as a whole, corresponding to a shape of the substrate 6202 of the light source unit 6203. A recess 6214 capable of accommodating the light source unit 6203 may be formed on the surface on which the light source unit 6203 is mounted.

A plurality of heat dissipating fins 6224 for heat dissipation may be formed to protrude on at least one outer side surface of the body 6204. In addition, fastening grooves 6234 extending in a longitudinal direction of the body 6204 may be formed on at least one end portion of outer side surfaces of the body 6204 disposed on the recess 6214. The cover 6207 may be fastened to the fastening grooves 6234.

At least one end of the body 6204 in a longitudinal direction may be open such that the body 6204 has a pipe structure in which at least one end thereof is open.

The driving unit 6209 may be disposed on the at least one open end of the body 6204 in the longitudinal direction, and supply driving power to the light source unit 6203. According to example embodiments of the present inventive concepts, at least one end of the body 6204 may be open, and the driving unit 6209 may be disposed on the at least one end of the body 6204. In example embodiments, the driving unit 6209 may be fastened to both open ends of the body 6204 to cover both of the open ends of the body 6204. The driving unit 6209 may include an electrode pin 6219 protruding outside.

The cover 6207 may be fastened to the body 6204 to cover the light source unit 6203. The cover 6207 may be formed of a light-transmissive material.

The cover 6207 may have a semi-circularly curved surface so that light is uniformly emitted to the outside. In addition, an overhanging 6217 engaged with the fastening groove 6234 of the body 6204 may be formed at a bottom of the cover 6207 combined with the body 6204 in a longitudinal direction of the cover 6207.

In example embodiments of the present inventive concepts, the cover 6207 is illustrated as having a semi-circularly curved surface, but is not limited thereto. For example, the cover 6207 may have a flat rectangular shape or another polygonal shape. The shape of the cover 6207 may be variously modified depending on a design of the lighting apparatus emitting light.

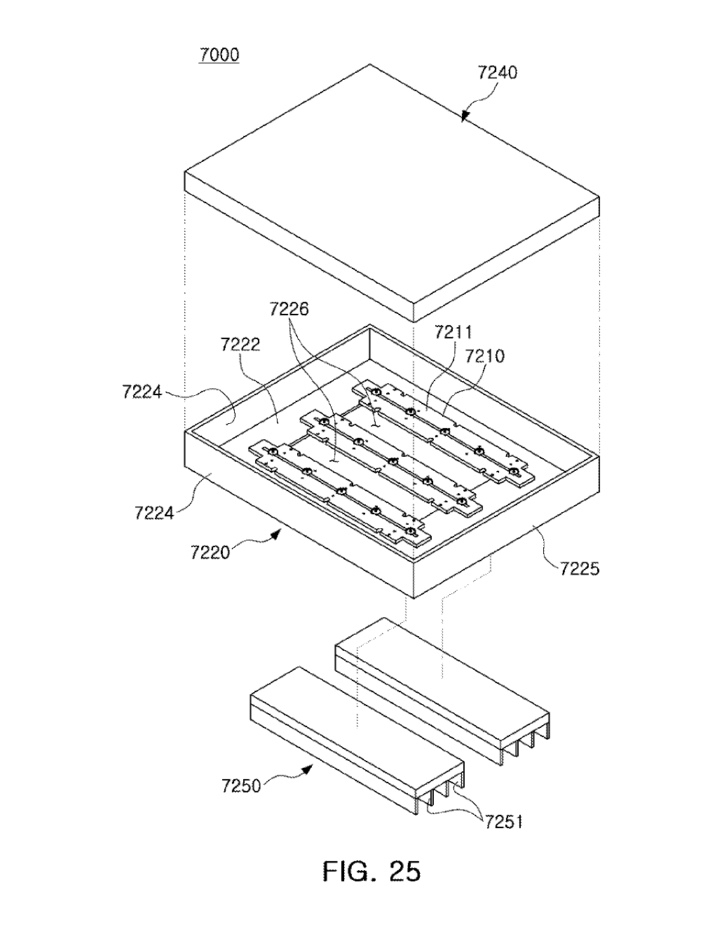

FIG. 25 is an exploded perspective view schematically illustrating a lighting apparatus according to example embodiments of the present inventive concepts.

Referring to FIG. 25, a lighting apparatus 7000 may have, for example, a surface light source type structure, and include a light source module 7210, a housing 7220, a cover 7240, and a heat sink 7250.

The light source module 7210 may include the semiconductor light emitting device or the light-emitting device package described above in example embodiments of the present inventive concepts. Accordingly, detailed descriptions thereof will be omitted. A plurality of light source modules 7210 may be mounted and arranged on a circuit board 7211.

The housing 7220 may have a box-type structure including one surface 7222 on which the light source module 7210 is mounted, and a side surface 7224 extending from edges of the one surface 7222. The housing 7220 may be formed of a material having high thermal conductivity, for example, a metal material, so as to release heat generated in the light source module 7210 to the outside.

A hole 7226 to which a heat sink 7250, to be described later, is to be inserted and engaged may be formed to pass through the one surface 7222 of the housing 7220. In addition, the circuit board 7211 on which the light source module 7210 installed on the one surface 7222 is mounted may be partly engaged on the hole 126 to be exposed to the outside.

The cover 7240 may be fastened to the housing 7220 to cover the light source module 7210. In addition, the cover 7240 may have a flat structure overall.

The heat sink 7250 may be engaged with the hole 7226 through the other surface 7225 of the housing 7220. In addition, the heat sink 7250 may be in contact with the light source module 7210 through the hole 7226 to release heat generated in the light source module 7210 to the outside. In order to increase heat dissipating efficiency, the heat sink 7250 may include a plurality of heat dissipating fins 7251. The heat sink 7250, like the housing 7220, may be formed of a material having high thermal conductivity.

Lighting apparatuses using light emitting devices may be roughly divided into indoor lighting apparatuses and outdoor lighting apparatuses according to the intended purpose thereof. Indoor LED lighting apparatuses may be used in bulb-type lamps, fluorescent lamps (LED-tubes), or flat-type lighting apparatuses, and mainly for retrofitting existing lighting apparatuses. Outdoor LED lighting apparatuses may be used in street lights, guard lamps, floodlights, decorative lights, or traffic lights.

In addition, the LED lighting apparatus may be utilized as interior or exterior light sources for vehicles. As interior light sources, LED lighting apparatuses may be used as various light sources for a vehicle interior lights, reading lamps, and instrument panels. As exterior light sources, LED lighting apparatuses may be used as all kinds of light sources, e.g., headlights, brake lights, turn indicators, fog lights, and running lights.

Further, the LED lighting apparatus may be used as light sources for robots or various types of mechanical equipment. In particular, an LED lighting apparatus using a specific wavelength band may promote the growth of plants, or stabilize the mood of a person or cure diseases as an emotional lighting apparatus.

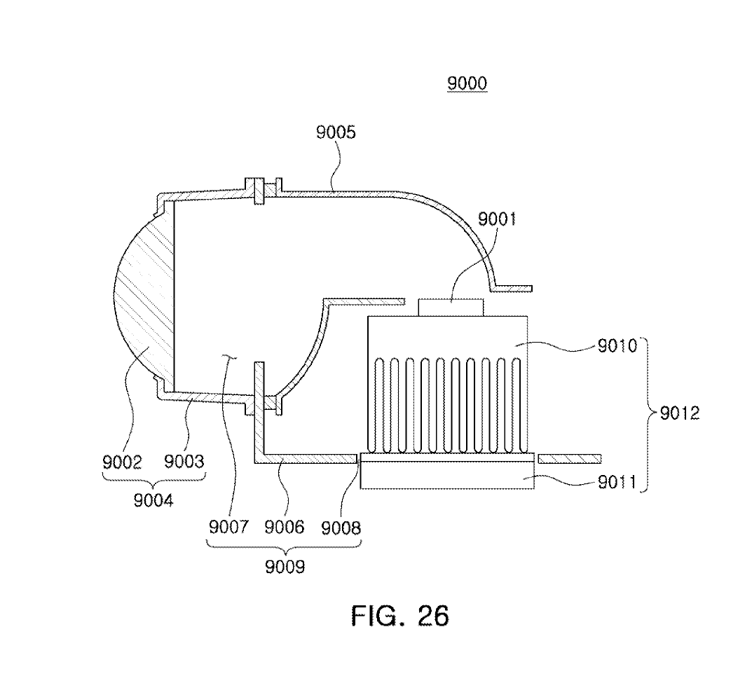

FIG. 26 illustrates an example in which a semiconductor light-emitting device according to example embodiments of the present inventive concepts is applied to a headlamp.

Referring to FIG. 26, a headlamp 9000 used as a vehicle lamp, or the like, may include a light source 9001, a reflective unit 9005, and a lens cover unit 9004. The lens cover unit 9004 may include a hollow-type guide 9003 and a lens 9002. The light source 9001 may include the semiconductor light emitting device or the light-emitting device package described above in example embodiments of the present inventive concepts.

The headlamp 9000 may further include a heat dissipation unit 9012 dissipating heat generated by the light source 9001 outwardly. In order to effectively dissipate heat, the heat dissipation unit 9012 may include a heat sink 9010 and a cooling fan 9011.

The headlamp 9000 may further include a housing 9009 fixedly supporting the heat dissipation unit 9012 and the reflective unit 9005. The housing 9009 may include a central hole 9008 formed in one surface thereof, in which the heat dissipation unit 9012 is coupled thereto.

The housing 9009 may include a front hole 9007 formed on the other surface integrally connected to the one surface and bent in a right angle direction and fixing the reflective unit 9005 to be disposed above the light source 9001. Accordingly, a front side of the housing 9009 may be open by the reflective unit 9005. The reflective unit 9005 is fixed to the housing 9009 such that the opened front side corresponds to the front hole 9007, and thereby light reflected by the reflective unit 9005 may pass through the front hole 9007 to be emitted outwardly.

As set forth above, according to example embodiments of the present inventive concepts, a semiconductor light-emitting device including regularly arranged microstructures in an edge thereof to improve light extraction efficiency, and a method of easily and efficiently manufacturing the semiconductor light-emitting device may be provided.

While example embodiments have been shown and described above, it will be apparent to those skilled in the art that modifications and variations could be made without departing from the scope of the inventive concepts as defined by the appended claims.

What is claimed is:

1. A semiconductor light-emitting device, comprising:
a light-emitting structure including a first conductivity-type semiconductor layer, an active layer, and a second conductivity-type semiconductor layer;
microstructures regularly arranged on the first conductivity-type semiconductor layer around the light-emitting structure; and
a gradient refractive layer on at least a portion of the microstructures, the gradient refractive layer having a lower refractive index than the first conductivity-type semiconductor layer.

2. The semiconductor light-emitting device of claim 1, wherein the microstructures have a hemispherical structure.

3. The semiconductor light-emitting device of claim 1, wherein a diameter of each of the microstructures is in a range of 2 μm to 3 μm.

4. The semiconductor light-emitting device of claim 1, wherein a height of each of the microstructures is lower than a height of an interface between the first conductivity-type semiconductor layer and the active layer.

5. The semiconductor light-emitting device of claim 1, wherein
the microstructures have one of a hexagonal lattice-shaped array and a tetragonal-lattice shaped array, and
a pitch between each of the microstructures is in a range of 2.5 μm to 8 μm.

6. The semiconductor light-emitting device of claim 1, wherein the microstructures are formed of the same material as the first conductivity-type semiconductor layer.

7. The semiconductor light-emitting device claim 1, wherein a refractive index of the gradient refractive layer has a value between a refractive index of the first conductivity-type semiconductor layer and a refractive index of silicon oxide.

8. The semiconductor light-emitting device of claim 1, wherein
the gradient refractive layer includes a plurality of material layers having different refractive indices, and
a thickness of each material layer is in a range of 10 nm to 200 nm.

9. The semiconductor light-emitting device of claim 1, wherein the microstructures are formed of a material having a lower refractive index than the first conductivity-type semiconductor layer.

10. The semiconductor light-emitting device of claim 9, wherein
the material having the lower refractive index than the first conductivity-type semiconductor layer is ZnO, and
a refractive index of the gradient refractive layer has a value between a refractive index of the ZnO and a refractive index of silicon oxide.

11. The semiconductor light-emitting device of claim 1, further comprising:
a first electrode connected to the first conductivity-type semiconductor layer,
wherein the microstructures are on the first conductivity-type semiconductor layer except for an area of the first conductivity-type semiconductor layer including the first electrode.

12. A semiconductor light-emitting device, comprising:
a first semiconductor layer and an encapsulating material on a substrate, the substrate including a first region and a second region;
microstructures between the first semiconductor layer and the encapsulating material in the second region; and
a gradient refractive layer between the encapsulating material and at least a portion of the microstructures in the second region, the gradient refractive layer having a lower refractive index than the microstructures and a greater refractive index than the encapsulating material.

13. The semiconductor light-emitting device of claim 16, wherein the encapsulating material is made of one of air and SiO₂.

14. The semiconductor light-emitting device of claim 16, further comprising:
a light-emitting structure on the first region of the substrate, the light-emitting structure including the first semiconductor layer, an active layer, and a second semiconductor layer.

15. The semiconductor light-emitting device of claim 18, wherein a height of each of the microstructures is lower than a height of an interface between the first semiconductor layer and the active layer.

16. The semiconductor light-emitting device of claim 18, further comprising:
a first electrode on the first semiconductor layer in the second region;
an ohmic contact layer on the second semiconductor layer in the first region; and
a second electrode on the ohmic contact layer in the first region,
wherein the microstructures are on the first semiconductor layer except for an area of the first semiconductor layer including the first electrode.

17. The semiconductor light-emitting device of claim 16, wherein the microstructures are formed of the same material as the first semiconductor layer.

18. The semiconductor light-emitting device of claim 21, wherein the microstructures and the first semiconductor layer are formed of n-type GaN.

19. The semiconductor light-emitting device claim 16, wherein a refractive index of the gradient refractive layer has a value between a refractive index of the first semiconductor layer and a refractive index of silicon oxide.

20. The semiconductor light-emitting device of claim 16, wherein
the microstructures are formed of a material having a lower refractive index than the first semiconductor layer,
the material having the lower refractive index than the first semiconductor layer is ZnO, and
a refractive index of the gradient refractive layer has a value between a refractive index of the ZnO and a refractive index of silicon oxide.
